(19) United States
(12) Patent Application Publication
(10) Pub. No.: US 2025/0287564 A1
(43) Pub. Date: Sep. 11, 2025

(54) SEMICONDUCTOR DEVICES AND MANUFACTURING METHODS THEREOF

(71) Applicant: Yangtze Memory Technologies Co., Ltd., Wuhan (CN)

(72) Inventors: ZongLiang Huo, Wuhan (CN); Wei Xu, Wuhan (CN); YuPing Xia, Wuhan (CN); WenBin Zhou, Wuhan (CN); Beibei Li, Wuhan (CN)

(21) Appl. No.: 18/671,526

(22) Filed: May 22, 2024

(30) Foreign Application Priority Data
Mar. 5, 2024 (CN) 202410257114.8

(51) Int. Cl. H10B 12/00

(52) U.S. Cl. CPC H10B 12/315; H10B 12/0335; H10B 12/482; H10B 12/488

(57) ABSTRACT

Examples of the present disclosure provide a semiconductor device and a manufacturing method thereof. The semiconductor device includes semiconductor pillars arranged along a first direction and a second direction, wherein the first direction intersects the second direction; gate lines spaced apart along the first direction, wherein each of the gate lines extends along the second direction and is connected with the semiconductor pillars arranged along the second direction; a first cavity between two adjacent gate lines along the first direction and extending along the second direction; bit lines spaced apart along the second direction, wherein each of the bit lines extends along the first direction and is connected with the semiconductor pillars arranged along the first direction; and a second cavity between two adjacent bit lines along the second direction and extending along the first direction, wherein the second cavity and the first cavity are connected.

### REFERENCE TO RELATED APPLICATION

The present application claims the benefit of priority to China Application No. 202410257114.8, filed on Mar. 5, 2024, the content of which is incorporated herein by reference in its entirety.

### TECHNICAL FIELD

Examples of the present disclosure relate to the field of semiconductor technology, and particularly to semiconductor devices and manufacturing methods thereof.

### BACKGROUND

A semiconductor device, e.g. a Dynamic Random Access Memory (DRAM), generally comprises a plurality of memory cells, each of which may comprise one transistor and one memory capacitor, wherein a gate of the transistor is connected with a word line, a source or a drain of the transistor is connected with the memory capacitor, and the drain or the source of the transistor is connected with a bit line.

### BRIEF DESCRIPTION OF THE DRAWINGS

FIGS. 1A to 1D are cross-sectional structural diagrams of a semiconductor device provided by an example;

FIG. 2 is a flow diagram of a manufacturing method of a semiconductor device provided by examples of the present disclosure;

FIGS. 3A to 3G are cross-sectional structural diagrams of a semiconductor device provided by a first example in a manufacturing process;

FIGS. 4A to 4G are cross-sectional structural diagrams of a semiconductor device provided by a second example in a manufacturing process;

FIGS. 5A to 5G are cross-sectional structural diagrams of a semiconductor device provided by a third example in a manufacturing process;

FIGS. 6A to 6G are cross-sectional structural diagrams of a semiconductor device provided by a fourth example in a manufacturing process;

FIGS. 7A to 7C are cross-sectional structural diagrams of a semiconductor device provided by a first example;

FIGS. 8A to 8C are cross-sectional structural diagrams of a semiconductor device provided by a second example;

FIGS. 9A to 9C are cross-sectional structural diagrams of a semiconductor device provided by a third example; and

FIGS. 10A to 10C are cross-sectional structural diagrams of a semiconductor device provided by a fourth example.

### DETAILED DESCRIPTION

The technical solutions in implementations of the present disclosure will be described below clearly and completely in conjunction with the implementations and the drawings of the present disclosure. Apparently, the implementations described are only part, but not all, of the implementations of the present disclosure. All other implementations obtained by those of ordinary skills in the art based on the implementations in the present disclosure without creative work shall fall in the scope of protection of the present disclosure.

In the description below, many specific details are presented to provide a more thorough understanding of the present disclosure. However, it is apparent to a person skilled in the art that the present disclosure may be implemented without one or more of these details. In other examples, in order to avoid confusion with the present disclosure, some technical features well-known in the field are not described. That is, all the features of the actual examples are not described here, and well-known functions and structures are not described in detail.

In the drawings, the sizes of a layer, a region, and an element and their relative sizes may be exaggerated for clarity. The same reference numeral represents the same element throughout.

It is to be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “directly adjacent to”, “directly connected to”, or “directly coupled to” other elements or layers, no intervening elements or layers are present. It should be understood that, although the terms first, second, third, etc., may be used to describe various elements, components, areas, layers and/or parts, these elements, components, areas, layers and/or parts should not be limited by these terms. These terms are only used to distinguish one element, component, area, layer or part from another element, component, area, layer or part. Thus, a first element, component, area, layer or part discussed below may be represented as a second element, component, area, layer or part, without departing from the teachings of the present disclosure. However, when the second element, component, area, layer or part is discussed, it does not mean that the first element, component, area, layer or part is necessarily present in the present disclosure.

The spatially relative terms, such as “beneath”, “below”, “lower”, “under”, “above”, “upper”, and the like, may be used herein for ease of description to describe the relationship of one element or feature to other elements or features as illustrated in the figures. It is to be understood that, the spatially relative terms are intended to further include different orientations of a device in use or operation in addition to the orientation depicted in the figures. For example, if the device in the drawings is flipped, the elements or the features described as “below” or “under” or “beneath” other elements may be oriented “on” the other elements or features. Thus, the example terms, “below” and “beneath”, may comprise both upper and lower orientations. The device may be orientated otherwise (rotated by 90 degrees or other orientations), and the spatially descriptive terms used herein are interpreted accordingly.

The terms used herein are only intended to describe the specific examples, and are not used as limitations of the present disclosure. As used herein, unless otherwise indicated expressly in the context, “a”, “an” and “the” in a singular form are also intended to comprise a plural form. It should also be understood that the terms “consist of” and/or “comprise”, when used in this specification, determine the presence of the feature, integer, step, operation, element and/or component, but do not preclude the presence or addition of one or more of other features, integers, steps, operations, elements, components, and/or groups. As used herein, the term “and/or” includes any and all combinations of related items listed.

In order to understand the present disclosure thoroughly, detailed steps and detailed structures will be proposed in the following description to set forth the technical solution of the present disclosure. The detailed descriptions of some examples of the present disclosure are as follows. However, the present disclosure may also have other implementations in addition to these detailed descriptions.

Currently, the manufacturing process of DRAM is relatively complicated, which may reduce its productivity and yield. Therefore, how to improve the manufacturing process of the semiconductor device to improve the performance of the semiconductor device has become an urgent problem to be solved.

With the development of DRAM technology, the size of memory cell is increasingly smaller, and its array architecture varies from 8 F² to 6 F² and then to 4 F². In addition, based on requirements of the DRAM on ions and leakage current, the architecture of the memory varies from a planar array transistor to a recess gate array transistor, then from the recess gate array transistor to a buried channel array transistor, and then from the buried channel array transistor to a vertical channel array transistor.

In some examples, for either the planar transistor or the buried transistor, the DRAM is composed of a plurality of memory cells each being composed of one transistor and one memory capacitor controlled by the transistor, that is, the DRAM comprises an architecture of one transistor and one memory capacitor (One Transistor One Capacitor, 1T1C). Its main operation principle is to represent whether a binary bit is 1 or 0 according to the amount of charges stored in the memory capacitor.

One of the architectures of the DRAM is described in detail below in conjunction with the drawings. It should be understood that the following description with respect to the DRAM architecture is only used to illustrate the present disclosure, and is not used to limit the scope of the present disclosure.

Before introducing the examples of the present disclosure, first, various directions that may be used to describe the semiconductor device in the examples of the present disclosure are defined. A thickness direction of a first substrate (or a second substrate) is defined as a Z direction, that is, a direction perpendicular to the first substrate is defined as the Z direction. An X direction and a Y direction that intersect with each other are defined in a plane perpendicular to the Z direction, that is, the X direction and the Y direction are both parallel to the first substrate (or the second substrate). In some examples, the X direction and the Y direction may be perpendicular to each other. In some other examples, the X direction and the Y direction may be also not perpendicular to each other. In the examples of the present disclosure, a first direction is the X direction, a second direction is the Y direction, a third direction is the Z direction, and an illustration will be made in the following examples by taking the X direction, the Y direction and the Z direction mutually perpendicular to each other as an example.

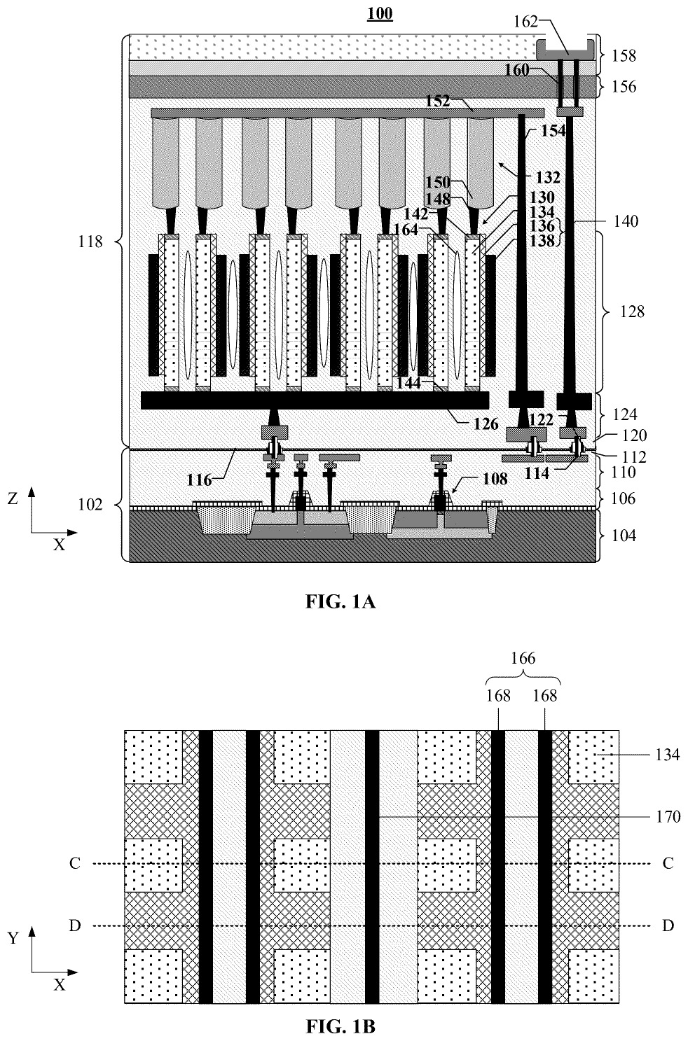

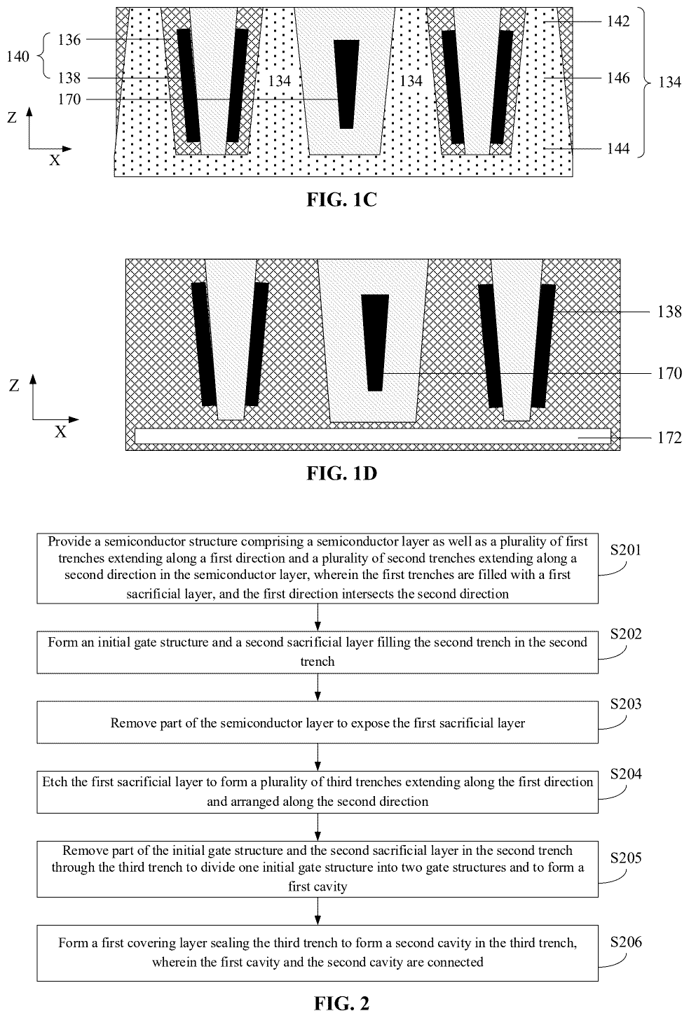

With reference to FIG. 1A, FIG. 1A is a cross-sectional structural diagram of a semiconductor device provided by an example. As shown in FIG. 1A, the semiconductor device 100 comprises a first semiconductor structure 102 and a second semiconductor structure 118 stacked over the first semiconductor structure 102 along a Z direction, wherein the first semiconductor structure 102 is connected with the second semiconductor structure 118 through a bonding interface 116, and the first semiconductor structure 102 may be connected with the second semiconductor structure 118 by means of hybrid bonding, etc. In some examples, the second semiconductor structure 118 may be bonded over the first semiconductor structure 102 at the bonding interface 116 in a face-to-face manner.

The first semiconductor structure 102 may comprise a first substrate 104, a peripheral circuit 106 on a side of the first substrate 104, and a first interconnect layer 110 on a side of the peripheral circuit 106 away from the first substrate 104, wherein the first interconnect layer 110 is used to transfer electrical signals of the peripheral circuit 106. The peripheral circuit 106 may comprise a plurality of transistors 108. In some examples, a trench isolation structure and a doped region (e.g., a well, a source and a drain of the transistor 108) may be also formed over or in the first substrate 104.

The first semiconductor structure 102 may further comprise a first bonding layer 112 at the bonding interface 116 and on a side of the first interconnect layer 110 away from the peripheral circuit 106. The first bonding layer 112 may comprise a plurality of first bonding contacts 114 and a dielectric layer electrically isolating the first bonding contacts 114. The first bonding contacts 114 and the surrounding dielectric layer in the first bonding layer 112 may be used for hybrid bonding. In contrast, the second semiconductor structure 118 may also comprise a second bonding layer 120 at the bonding interface 116 and on a side of the first bonding layer 112 away from the first interconnect layer 110. The second bonding layer 120 may comprise a plurality of second bonding contacts 122 and a dielectric layer electrically isolating the second bonding contacts 122. The second bonding contacts 122 and the surrounding dielectric layer in the second bonding layer 120 may be used for hybrid bonding. Here, the second bonding contacts 122 are in contact with the first bonding contacts 114 at the bonding interface 116.

In some examples, the peripheral circuit 106 may further comprise a word line (WL) (also referred to as a gate line) and a word line driver/row decoder coupled to a second interconnect layer 124 through the second bonding contacts 122 in the second bonding layer 120 and the first bonding contacts 114 in the first bonding layer 112 and the first interconnect layer 110. In some other examples, the peripheral circuit 106 may further comprise a bit line (BL) and a bit line driver/column decoder coupled to the second interconnect layer 124 through the second bonding contacts 122 in the second bonding layer 120 and the first bonding contacts 114 in the first bonding layer 112 and the first interconnect layer 110.

With reference to FIG. 1A, the second semiconductor structure 118 further comprises a memory cell array over the second interconnect layer 124, wherein the memory cell array may comprise a plurality of memory cells 128, a second substrate 156 over the memory cells 128, and a third interconnect layer 158 over the second substrate 156. Here, the second interconnect layer 124 comprises a bit line 126 above the second bonding layer 120, wherein the bit line 126 is used for transferring electrical signals. A cross section of the semiconductor device 100 of FIG. 1A may be taken along a bit line direction (i.e., the X direction), and one bit line 126 in the second interconnect layer 124 extending laterally in the X direction may be coupled to a row of vertical transistors 130.

Here, each memory cell 128 may comprise a vertical transistor 130 and a memory capacitor coupled to the vertical transistor 130. The vertical transistor 130 comprises a semiconductor pillar 134 extending vertically (i.e., the Z direction), and a gate structure 140 in the bit line direction (i.e., the X direction) and in contact with a side of the semiconductor pillar 134. In some other examples, the gate structure may also be all around the semiconductor pillar, half around the semiconductor pillar, on two opposite sides of the semiconductor pillar, and the like, which is no longer repeated here. Here, the gate structure 140 comprises a gate layer 138, and a gate dielectric layer 136 between the gate layer 138 and the semiconductor pillar 134.

In some examples, the semiconductor pillar 134 has two ends (an upper end and a lower end) in the vertical direction (i.e., the Z direction), and at least one end (e.g., the lower end in FIG. 1A) extends beyond the gate dielectric layer 136 into an interlayer dielectric (ILD) layer in the vertical direction (i.e., the Z direction). In some examples, one end (e.g., the upper end in FIG. 1A) of the semiconductor pillar 134 is flush with a respective end of the gate dielectric layer 136. In some examples, the two ends (the upper end and the lower end) of the semiconductor pillar 134 extend beyond the gate layer 138 into the ILD in the vertical direction (i.e., the Z direction) respectively. That is, the semiconductor pillar 134 may have a vertical size greater than a vertical size (e.g., a height in the Z direction) of the gate layer 138, and both the upper end and the lower end of the semiconductor pillar 134 are not flush with the respective ends of the gate layer 138. As such, a short circuit between the bit line 126 and the gate layer 138 or between the gate layer 138 and the memory capacitor 132 may be avoided.

The vertical transistor 130 may further comprise a source 142 and a drain 144 (locations of the source and the drain may be interchangeable) disposed at the two ends (the upper end and the lower end) of the semiconductor pillar 134 in the Z direction respectively. In some implementations, the source 142 is coupled to the memory capacitor 132, and the drain 144 is coupled to the bit line 126.

Since the gate layer 138 may be part of a gate line or extend in a gate line direction as a gate line, the second semiconductor structure 118 of the semiconductor device 100 may also comprise a plurality of gate lines each extending in the gate line direction (i.e., the Y direction). Here, each gate line may be coupled to a column of vertical transistors 130.

The vertical transistor 130 vertically extends through and is in contact with the gate line, and the drain 144 of the vertical transistor 130 at the lower end thereof is in contact with the bit line 126. Therefore, due to the vertical arrangement of the vertical transistor 130, the gate line and the bit line 126 may be disposed in different planes in the vertical direction, which simplifies routing of the gate line and the bit line 126. Here, the vertical transistor 130 may be arranged in a mirror-symmetrical manner so as to increase the density of the memory cells 128 in the bit line direction (i.e., the X direction). The two adjacent vertical transistors 130 in the bit line direction are mirror-symmetrical to each other with respect to a trench isolation structure 164, that is to say, the second semiconductor structure 118 may comprise a plurality of trench isolation structures 164, wherein each trench isolation structure 164 and the gate line extend in parallel in the gate line direction (i.e., the Y direction), and are disposed between two adjacent columns of semiconductor pillars 134 of the vertical transistor 130. In some implementations, the columns of vertical transistors 130 separated by the trench isolation structure 164 are mirror-symmetrical to each other with respect to the trench isolation structure 164. It should be understood that the trench isolation structure 164 may comprise air gaps each laterally disposed between the two adjacent semiconductor pillars 134.

As shown in FIG. 1A, the memory capacitor 132 comprises a first electrode 148 above the source 142 (e.g., the upper end of the semiconductor pillar 134) of the vertical transistor 130 and in contact with the source 142, a capacitor dielectric layer 150 above and in contact with the first electrode 148, and a second electrode 152 above and in contact with the capacitor dielectric layer 150. That is, the memory capacitor 132 may be a vertical capacitor, wherein the first electrode 148, the capacitor dielectric layer 150 and the second electrode 152 are stacked vertically (i.e., along the Z direction), and the capacitor dielectric layer 150 may be sandwiched between the first electrode 148 and the second electrode 152. In some implementations, an interconnect structure (e.g., a metal silicide layer) is formed between the drain 144 and the bit line 126 or between the source 142 and the first electrode 148 to reduce contact resistance.

As shown in FIG. 1A, the second semiconductor structure 118 may further comprise a capacitor contact 154 in contact with a common plate of the second electrode 152 to couple the second electrode 152 of the memory capacitor 132 to the peripheral circuit 106 or directly to ground. In some implementations, an ILD forming the memory capacitor 132 has the same dielectric material (e.g., silicon oxide) as two ILDs extending into the semiconductor pillar 134. A structure and configuration of the memory capacitor 132 may include any suitable structure and configuration, for example, a planar capacitor, a stack capacitor, a multi-fin capacitor, a cylinder capacitor, a trench capacitor or a substrate-plate capacitor.

As shown in FIG. 1A, the vertical transistor 130 vertically extends through and is in contact with the gate line, the drain 144 of the vertical transistor 130 at the lower end thereof is in contact with the bit line 126, and the source 142 of the vertical transistor 130 at the upper end thereof is in contact with the first electrode 148 of the memory capacitor 132. That is, due to the vertical arrangement of the vertical transistor 130, the bit line 126 and the memory capacitor 132 can be disposed in different planes in the vertical direction, and coupled to opposite ends of the vertical transistor 130 of the memory cell 128 in the vertical direction. In some implementations, the bit line 126 and the memory capacitor 132 are disposed on the opposite sides of the vertical transistor 130 in the vertical direction, which simplifies routing of the bit line 126 and reduces coupling capacitance between the bit line 126 and the memory capacitor 132 compared with a conventional memory cell in which the bit line and the memory capacitor are disposed on the same side of a planar transistor.

In some examples, the vertical transistor 130 is vertically disposed between the memory capacitor 132 and the bonding interface 116. That is, the vertical transistor 130 may be arranged closer to the peripheral circuit 106 of the first semiconductor structure 102 and the bonding interface 116 than the memory capacitor 132. Since the bit line 126 and the memory capacitor 132 are coupled to the opposite ends of the vertical transistor 130, the bit line 126 (as part of the second interconnect layer 124) is vertically disposed between the vertical transistor 130 and the bonding interface 116 to reduce interconnect routing distance and complexity.

In some examples, the second semiconductor structure 118 further comprises a second substrate 156 disposed above the memory cell 128, and a pad-out third interconnect layer 158 above the memory cell 128. The pad-out third interconnect layer 158 may comprise interconnects (e.g., a contact pad 162) in one or more ILDs.

In some examples, the second semiconductor structure 118 further comprises one or more contacts 160 extending through part of the pad-out third interconnect layer 158 and the second substrate 156 to couple the pad-out third interconnect layer 158 to the memory cell 128 and the second interconnect layer 124. As such, the peripheral circuit 106 may be coupled to the memory cell 128 through the first interconnect layer 110 and the second interconnect layer 124 as well as the second bonding layer 120 and the first bonding layer 112, and the peripheral circuit 106 and the memory cell 128 may be coupled to an external circuit through the contacts 160 and the pad-out third interconnect layer 158.

The second semiconductor structure 118 is illustrated in detail below with reference to FIGS. 1B to 1D. FIG. 1B is an XY cross-sectional structural diagram of a semiconductor device provided by an example, FIG. 1C is an XZ cross-sectional structural diagram along a C-C cross-section in FIG. 1B, and FIG. 1D is an XZ cross-sectional structural diagram along a D-D cross-section in FIG. 1B.

As shown in FIG. 1B, the semiconductor device 100 comprises: a plurality of semiconductor pillars 134 arranged in an array along an X direction and a Y direction; a plurality of gate line groups 166 spaced apart along the X direction, wherein each of the plurality of gate line groups 166 is located between two adjacent ones of the semiconductor pillars 134 along the X direction, and comprises two gate lines 168 spaced apart along the X direction, and each gate line 168 extends along the Y direction and is connected with the plurality of semiconductor pillars 134 arranged along the Y direction; a plurality of shielding structures 170 spaced apart along the X direction and extending along the Y direction, wherein each of the plurality of shielding structures 170 is located between two adjacent ones of the gate line groups 166 along the X direction; and a plurality of bit lines spaced apart along the Y direction, wherein each bit line extends along the X direction and is connected with the plurality of semiconductor pillars 134 arranged along the X direction.

Here, a material of the shielding structure 170 may include, for example, a metal material. A shielding effect of the shielding structure 170 may be also enhanced by applying a shielding voltage signal to the shielding structure 170.

As shown in FIG. 1C, the semiconductor device 100 further comprises a gate structure 140 on at least a sidewall of the semiconductor pillar 134, wherein the gate structure 140 comprises a gate dielectric layer 136 and a gate layer 138, and the gate dielectric layer 136 is in contact with the semiconductor pillar 134. The semiconductor pillar 134 comprises, along a Z direction, a source 142, a drain 144 and a channel region 146 between the source 142 and the drain 144. Each bit line may be connected with the plurality of sources 142 or drains 144 arranged along the X direction; and correspondingly, a memory capacitor may be connected with the drain 144 or the source 142.

As shown in FIGS. 1C and 1D, the semiconductor device 100 further comprises a bit line gap 172 located between the two adjacent bit lines along the Y direction and extending along the X direction.

In the above technical solution, the shielding structure is disposed between two adjacent ones of the gate line groups along the X direction, which can reduce the capacitive coupling effect between the adjacent gate line groups, thereby improving the performance of the semiconductor device. However, the manufacturing process of the shielding structure is difficult and costly, which is unfavorable to size shrinking of the semiconductor device in future.

In view of this, examples of the present disclosure provide a semiconductor device and a manufacturing method thereof.

With reference to FIG. 2, FIG. 2 is a flow diagram of a manufacturing method of a semiconductor device provided by examples of the present disclosure. As shown in FIG. 2, examples of the present disclosure provide a manufacturing method of a semiconductor device, comprising:
S201: providing a semiconductor structure comprising a semiconductor layer as well as a plurality of first trenches extending along a first direction and a plurality of second trenches extending along a second direction in the semiconductor layer, wherein the first trenches are filled with a first sacrificial layer, and the first direction intersects the second direction;
S202: forming an initial gate structure and a second sacrificial layer filling the second trench in the second trench;
S203: removing part of the semiconductor layer to expose the first sacrificial layer;
S204: etching the first sacrificial layer to form a plurality of third trenches extending along the first direction and arranged along the second direction;
S205: removing part of the initial gate structure and the second sacrificial layer in the second trench through the third trench to divide one initial gate structure into two gate structures and to form a first cavity; and
S206: forming a first covering layer sealing the third trench to form a second cavity in the third trench, wherein the first cavity and the second cavity are connected.

In the examples of the present disclosure, the first cavity between the two adjacent gate lines and the second cavity between the two adjacent bit lines are connected, such that the density of the semiconductor device can be increased, the difficulty and cost of manufacturing process of the semiconductor device can be reduced, and the capacitive coupling effect between the adjacent gate lines and between the adjacent bit lines can also be reduced, so as to improve the performance of the semiconductor device and facilitate the size shrinking of the semiconductor device in future.

In the examples of the present disclosure, the first cavity is disposed between the two adjacent gate lines in the same gate line group, and the second cavity is disposed between the two adjacent bit lines, and the first cavity and the second cavity are connected. A third cavity is further disposed between the two adjacent gate line groups. In a first example of the present disclosure, the first cavity, the second cavity and the third cavity are connected. In a second example of the present disclosure, the first cavity and the second cavity are connected, the first cavity and the third cavity are not connected, and the second cavity and the third cavity are not connected.

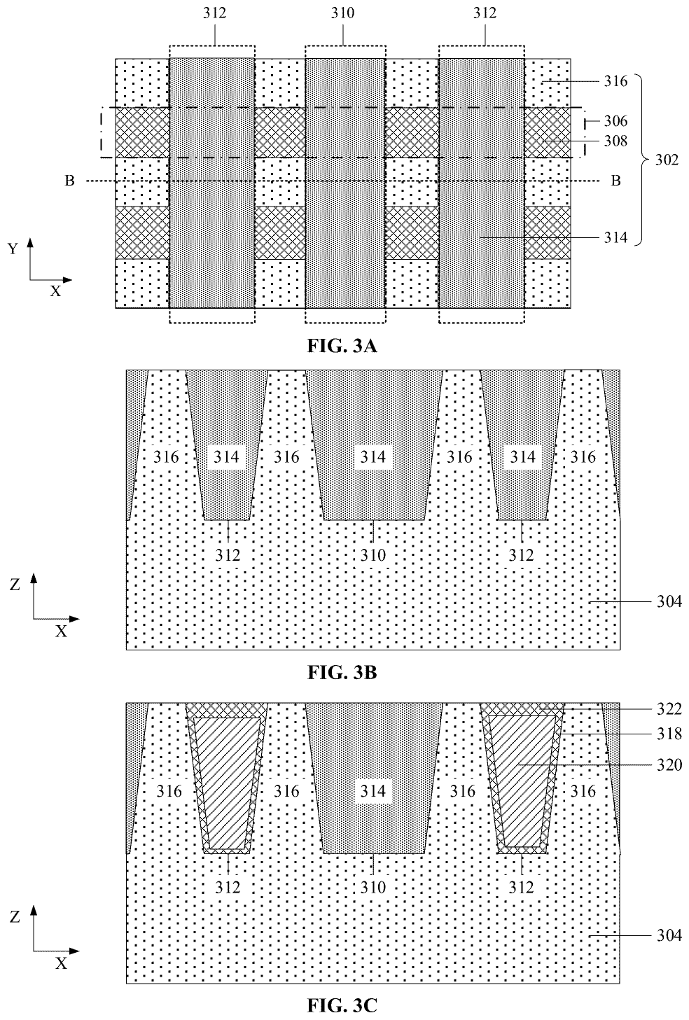

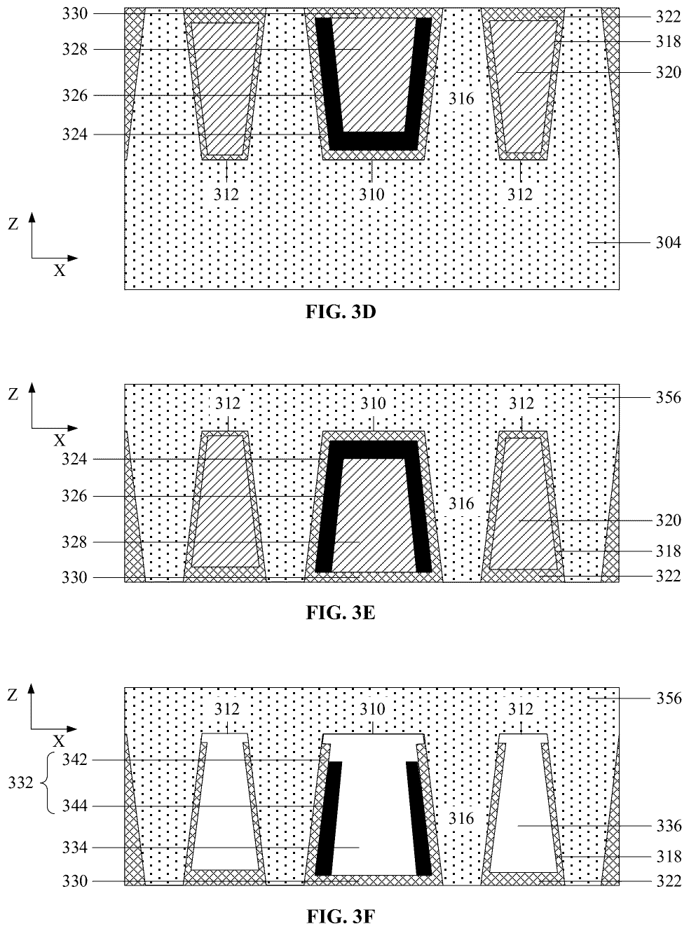

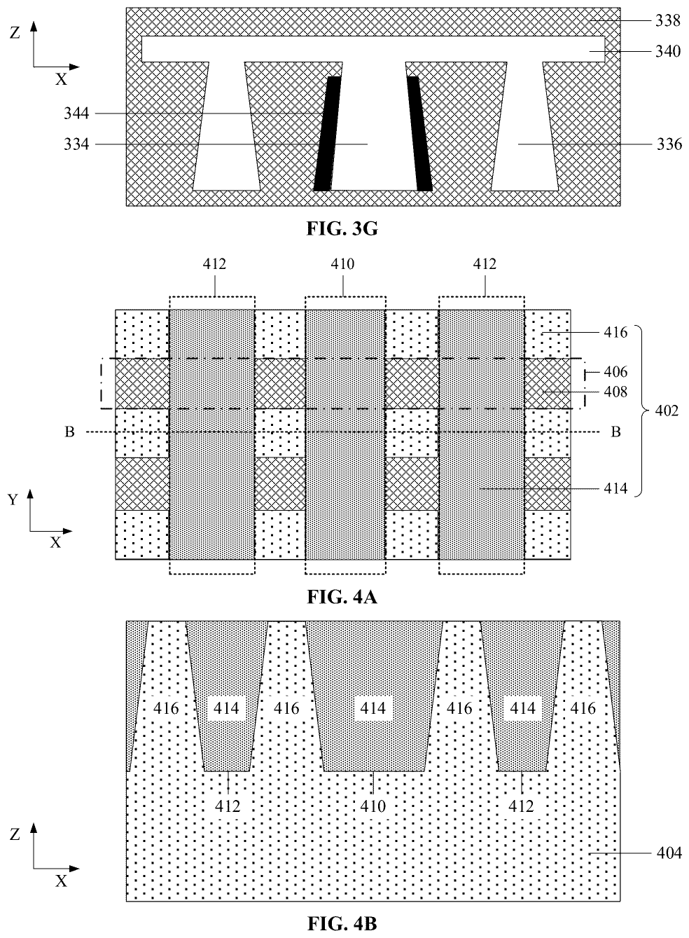

With reference to FIGS. 3A to 3G, FIGS. 3A to 3G are cross-sectional structural diagrams of a semiconductor device provided by a first example in a manufacturing process. The manufacturing process of the semiconductor device provided by the first example of the present disclosure will be illustrated in detail below in conjunction with FIGS. 3A to 3G.

In the examples of the present disclosure, in S201, a semiconductor structure 302 is provided, and comprises a semiconductor layer 304 as well as a plurality of first trenches 306 extending along an X direction and a plurality of second trenches 310 extending along a Y direction in the semiconductor layer 304, wherein the first trenches 306 are filled with a first sacrificial layer 308; and the X direction intersects the Y direction.

In some examples, the semiconductor structure 302 further comprises a plurality of fourth trenches 312 extending along the Y direction, wherein the second trenches 310 and the fourth trenches 312 are arranged alternately along the X direction, the depths of the first trenches 306 along a Z direction are greater than the depths of the fourth trenches 312 along the Z direction, and the depths of the second trenches 310 and the fourth trenches 312 along the Z direction may be the same.

FIG. 3A is an XY cross-sectional structural diagram of the semiconductor device, and FIG. 3B is an XZ cross-sectional structural diagram along a B-B cross-section in FIG. 3A. As shown in FIGS. 3A and 3B, the semiconductor layer 304 is provided; the semiconductor layer 304 is etched along the Z direction to form the plurality of first trenches 306 (as shown by a dashed box in FIG. 3A) extending along the X direction and a plurality of semiconductor strips extending along the X direction; a sacrificial material is filled in the first trench 306 to form the first sacrificial layer 308; the semiconductor strips and the first sacrificial layer 308 are etched along the Z direction to form the plurality of second trenches 310 (as shown by a dotted box in FIG. 3A) and the plurality of fourth trenches 312 (as shown by a dotted box in FIG. 3A) extending along the Y direction, wherein the second trenches 310 and the fourth trenches 312 are arranged alternately along the X direction; and the sacrificial material is filled in the second trench 310 and the fourth trench 312 to form a fourth sacrificial layer 314.

As shown in FIG. 3A, the first trench 306 extending along the X direction, the second trench 310 extending along the Y direction and the fourth trench 312 extending along the Y direction jointly divide the semiconductor layer 304 into a plurality of semiconductor pillars 316 arranged in an array along the X direction and the Y direction. In other words, the first sacrificial layer 308 extending along the X direction and the fourth sacrificial layer 314 extending along the Y direction jointly divide the semiconductor layer 304 into the plurality of semiconductor pillars 316 arranged in an array along the X direction and the Y direction.

Here, the semiconductor layer 304 may comprise at least one elemental semiconductor material (e.g., a silicon (Si) substrate, a germanium (Ge) substrate, etc.), at least one III-V compound semiconductor material (e.g., a gallium nitride (GaN) substrate, a gallium arsenide (GaAs) substrate, an indium phosphide (InP) substrate, etc.), at least one II-VI compound semiconductor material, at least one organic semiconductor material or other semiconductor materials known in the art, and may also comprise other substrates containing a semiconductor material, e.g., a silicon on insulator (SOI) substrate, a germanium on insulator (GeOI) substrate, a polycrystalline semiconductor layer on an insulation layer and a silicon germanium substrate, etc.

In some examples, the depth of the first trench 306 along the Z direction is greater than the depth of the second trench 310 along the Z direction, and the depth of the first trench 306 along the Z direction is greater than the depth of the fourth trench 312 along the Z direction. On this basis, the height of the first sacrificial layer 308 along the Z direction is greater than the height of the fourth sacrificial layer 314 along the Z direction.

In some examples, the depth of the second trench 310 along the Z direction and the depth of the fourth trench 312 along the Z direction may be the same.

Here, a process of forming the first trench 306, the second trench 310 and the fourth trench 312 by etching may include, but is not limited to, dry etching, wet etching or a combination thereof. For example, the second trench 310 and the fourth trench 312 may be formed using All In One Etch (AIO ET).

In some examples, materials of the first sacrificial layer 308 and the fourth sacrificial layer 314 may be the same or different.

Here, the materials of the first sacrificial layer 308 and the fourth sacrificial layer 314 may include, but are not limited to, silicon oxide, silicon nitride or silicon oxynitride, etc.

Here, a process of forming the first sacrificial layer 308 and the fourth sacrificial layer 314 may include, but is not limited to, chemical vapor deposition (CVD), physical vapor deposition (PVD) or atomic layer deposition (ALD), etc.

Here, a sacrificial material is filled in the first trench 306 to form a first sacrificial material layer filling the first trench 306 and covering a surface of the semiconductor layer 304; and the first sacrificial material layer is planarized to form the first sacrificial layer 308 exposing the surface of the semiconductor layer 304. Similarly, a sacrificial material may be filled in the second trench 310 and the fourth trench 312 to form the fourth sacrificial layer 314.

Here, the planarization processing may include, but is not limited to, chemical mechanical polishing (CMP).

Here, the shape of orthographic projection of the semiconductor pillar 316 on an XY plane may include, but is not limited to, a quadrangle, a circle, or an ellipse, etc. The shape of orthographic projection of the semiconductor pillar 316 on the XY plane is not specifically limited in the present disclosure. FIG. 3A makes an illustration by taking the shape of orthographic projection of the semiconductor pillar 316 on the XY plane as a quadrangle as an example. The semiconductor pillar 316 comprises two sidewalls oppositely disposed along the X direction and two sidewalls oppositely disposed along the Y direction.

Here, first the first trench 306 extending along the X direction may be formed by etching, and then the second trench 310 and the fourth trench 312 extending along the Y direction may be formed by etching; alternatively, first the second trench 310 and the fourth trench 312 extending along the Y direction may be formed by etching, and then the first trench 306 extending along the X direction may be formed by etching. In the present disclosure, there are no specific limitations to the etching sequence for forming the first trench 306, the second trench 310 and the fourth trench 312 by etching.

FIGS. 3C to 3G are XZ cross-sectional structural diagrams along a cross-section parallel to the X direction. As shown in FIG. 3C, in some examples, the method further comprises: removing the fourth sacrificial layer 314 in the fourth trench 312; forming a second dielectric layer 318 covering a sidewall and bottom of the fourth trench 312; filling a sacrificial material in the fourth trench 312 to form a third sacrificial layer 320; removing part of the third sacrificial layer 320 by back-etching, such that a surface of the third sacrificial layer 320 is lower than the surface of the semiconductor layer 304; and filling a dielectric material in the fourth trench 312 to form a third dielectric layer 322.

In an example, the sacrificial material is filled in the fourth trench 312 to form a third sacrificial material layer filling the fourth trench 312 and covering the surface of the semiconductor layer 304; the third sacrificial material layer is planarized to form the third sacrificial layer 320 exposing the surface of the semiconductor layer 304, such that the surface of the third sacrificial layer 320 is substantially flush with the surface of the semiconductor layer 304; part of the third sacrificial layer 320 is removed by back-etching, such that the surface of the third sacrificial layer 320 is lower than the surface of the semiconductor layer 304; the dielectric material is filled in the fourth trench 312 to form the third dielectric material layer covering the surface of the semiconductor layer 304; the third dielectric material layer is planarized to form the third dielectric layer 322 exposing the surface of the semiconductor layer 304, such that the surface of the third dielectric layer 322 is substantially flush with the surface of the semiconductor layer 304.

Here, “substantially flush” may be interpreted as that after chemical mechanical polishing processing, the surface of the formed third dielectric layer 322 and the surface of the semiconductor layer 304 are flush on the same plane, and that during the chemical mechanical polishing process, the surface of the formed third dielectric layer 322 and the surface of the semiconductor layer 304 are not flush on the same plane within the error range of the process.

Here, the second dielectric layer 318 covers the bottom and sidewall of the third sacrificial layer 320, and the third dielectric layer 322 covers the top of the third sacrificial layer 320. The third sacrificial layer 320 will be removed during a subsequent process to form the third cavity, so as to reduce the capacitive coupling effect between two adjacent gate line groups (or two gate lines).

In some examples, materials of the second dielectric layer 318 and the third dielectric layer 322 may be the same or different.

Here, the materials of the second dielectric layer 318 and the third dielectric layer 322 may include, but are not limited to, silicon oxide.

Here, a material of the third sacrificial layer 320 may include, but is not limited to, silicon oxide, silicon nitride or silicon oxynitride, etc.

Here, a process of forming the second dielectric layer 318, the third dielectric layer 322 and the third sacrificial layer 320 may include, but is not limited to, CVD, PVD or ALD, etc.

In the examples of the present disclosure, in S202, an initial gate structure 326 and a second sacrificial layer 328 filling the second trench 310 are formed in the second trench 310.

As shown in FIG. 3D, the fourth sacrificial layer 314 in the second trench 310 is removed. In some examples, S202 comprises: forming a first dielectric layer 324 covering a sidewall and bottom of the second trench 310; forming the initial gate structure 326 covering the sidewall and the bottom of the second trench 310; filling a sacrificial material in the second trench 310 to form the second sacrificial layer 328; back-etching part of the initial gate structure 326 and the second sacrificial layer 328, such that surfaces of the initial gate structure 326 and the second sacrificial layer 328 are lower than the surface of the semiconductor layer 304; and filling a dielectric material in the second trench 310 to form a fourth dielectric layer 330.

In an example, the initial gate structure 326 covering the sidewall and the bottom of the second trench 310 is formed; the sacrificial material is filled in the second trench 310 to form the second sacrificial layer 328, such that a surface of the initial gate structure 326, a surface of the second sacrificial layer 328 and the surface of the semiconductor layer 304 are substantially flush; part of the initial gate structure 326 and the second sacrificial layer 328 is removed by back-etching, such that the surfaces of both the initial gate structure 326 and the second sacrificial layer 328 are lower than the surface of the semiconductor layer 304; the dielectric material is filled in the second trench 310 to form a fourth dielectric material layer covering the surface of the semiconductor layer 304; the fourth dielectric material layer is planarized to form the fourth dielectric layer 330 exposing the surface of the semiconductor layer 304, such that a surface of the fourth dielectric layer 330 is substantially flush with the surface of the semiconductor layer 304.

Here, during a front side process of the semiconductor layer, the second sacrificial layer 328 may be buried in the second trench 310, and the third sacrificial layer 320 may be buried in the fourth trench 312. Subsequently during a back side process of the semiconductor layer, the second sacrificial layer 328 in the second trench 310 may be removed to form the first cavity, and the third sacrificial layer 320 in the fourth trench 312 may be removed to form the third cavity. In addition, the first cavity, the third cavity, and the second cavity between the subsequent bit lines may be also connected, and the first cavity, the third cavity and the second cavity are formed integrally.

Here, “substantially flush” may be interpreted as that after chemical mechanical polishing processing, the surface of the formed fourth dielectric layer 330 and the surface of the semiconductor layer 304 are flush on the same plane, and that during the chemical mechanical polishing process, the surface of the formed fourth dielectric layer 330 and the surface of the semiconductor layer 304 are not flush on the same plane within the error range of the process.

Here, the first dielectric layer 324 (or the initial gate structure 326) covers the bottom and sidewall of the second sacrificial layer 328, and the fourth dielectric layer 330 covers the top of the second sacrificial layer 328. The second sacrificial layer 328 will be removed during a subsequent process to form the first cavity, so as to reduce the capacitive coupling effect between the two adjacent gate lines.

In some examples, materials of the first dielectric layer 324 and the fourth dielectric layer 330 may be the same or different.

Here, the materials of the first dielectric layer 324 and the fourth dielectric layer 330 may include, but are not limited to, silicon oxide.

Here, a material of the initial gate structure 326 may comprise a conductive material, e.g., a metal material. In an example, the material of the initial gate structure 326 may include tungsten.

In the examples of the present disclosure, the materials of the second sacrificial layer 328 and the third sacrificial layer 320 or be the same or different.

Here, a process of forming the first dielectric layer 324, the fourth dielectric layer 330, the second sacrificial layer 328 and the initial gate structure 326 may include, but is not limited to, CVD, PVD or ALD, etc.

In the examples of the present disclosure, in S203, part of the semiconductor layer 304 is removed to expose the first sacrificial layer 308.

As shown in FIG. 3E, the back side of the semiconductor layer 304 is thinned to expose the first sacrificial layer 308. Since the height of the first sacrificial layer 308 along the Z direction is greater than the height of the fourth sacrificial layer 314 along the Z direction, the remaining semiconductor layer forms the bit lines 356 while removing part of the semiconductor layer 304 to expose the first sacrificial layer 308. The plurality of bit lines 356 are spaced apart along the Y direction, and the bit lines 356 extending along the X direction are connected with the plurality of semiconductor pillars 316 spaced apart along the X direction.

Here, the semiconductor pillar 316 comprises, along the Z direction, a source, a drain and a channel region between the source and the drain, wherein each bit line may be connected with the plurality of sources or drains arranged along the X direction; and correspondingly, the memory capacitor may be connected with the source or the drain.

In the examples of the present disclosure, in S204, the first sacrificial layer 308 is etched to form the plurality of third trenches extending along the X direction and arranged along the Y direction.

Here, part of the first sacrificial layer 308 may be removed from the back side of the semiconductor layer 304 to form the plurality of third trenches extending along the X direction and arranged along the Y direction, wherein the third trench is located between two adjacent bit lines 356 along the Y direction.

In the examples of the present disclosure, in S205, part of the initial gate structure 326 and the second sacrificial layer 328 in the second trench 310 are removed through the third trench to divide one initial gate structure 326 into two gate structures 332 and to form the first cavity 334.

As shown in FIG. 3F, the first dielectric layer 324 covering the bottom of the second trench 310 is removed through the third trench to expose the initial gate structure 326 covering the bottom of the second trench 310. At this point, the first dielectric layer 324 covering the two oppositely disposed sidewalls of the second trench 310 forms a gate dielectric layer 342. The initial gate structure 326 covering the bottom of the second trench 310 is removed through the third trench to divide one initial gate structure 326 into two gate layers 344, that is, the initial gate structure 326 covering the two oppositely disposed sidewalls of the second trench 310 forms the gate layers 344, wherein the gate dielectric layer 342 covering the sidewall of the semiconductor pillar 316 and the gate layer 344 covering the gate dielectric layer 342 jointly form the gate structure 332. In addition, the second sacrificial layer 328 in the second trench 310 is removed through the third trench to form the first cavity 334.

Here, the gate structure 332 is located on a sidewall of the semiconductor pillar 316, and the gate structures 332 of the plurality of semiconductor pillars arranged along the Y direction are connected to form a gate line. Two gate lines in the same second trench 310 form a gate line group that is located between two adjacent semiconductor pillars 316 along the X direction, and each gate line group comprises two gate lines spaced apart along the X direction and extending along the Y direction.

Here, the first cavity 334 is located between the two gate lines in the same gate line group, and the first cavity 334 extends along the Y direction.

In some examples, at the same time as performing S205, the method further comprises: removing the third sacrificial layer 320 in the fourth trench 312 through the third trench to form the third cavity 336 in the fourth trench 312.

As shown in FIG. 3F, the second dielectric layer 318 covering the bottom of the fourth trench 312 is removed through the third trench to expose the third sacrificial layer 320 covering the bottom of the fourth trench 312; and the third sacrificial layer 320 in the fourth trench 312 is removed through the third trench to form the third cavity 336.

Here, the third cavity 336 is located between the two adjacent semiconductor pillars 316 along the X direction, or the third cavity 336 is located between the two adjacent gate line groups along the X direction, and the third cavity 336 extends along the Y direction.

Here, the third cavity 336 has two surfaces disposed oppositely along the Z direction. Since the third cavity 336 is formed by removing the third sacrificial layer 320, the surface of the third cavity 336 away from the bit line 356 is a flat surface, that is, a surface of the third dielectric layer 322 close to the third cavity 336 is a flat surface.

In the examples of the present disclosure, in S206, a first covering layer 338 sealing the third trench is formed to form a second cavity 340 in the third trench, wherein the first cavity 334, the second cavity 340 and the third cavity 336 are connected.

As shown in FIG. 3G, the first covering layer 338 sealing the third trench is formed to form the second cavity 340 in the third trench, wherein the first cavity 334, the second cavity 340 and the third cavity 336 are connected.

Here, the second cavity 340 is located between the two adjacent bit lines 356 along the Y direction and extends along the X direction.

Here, a material of the first covering layer 338 may include, but is not limited to, an insulation material, e.g., silicon oxide.

Here, the second cavity 340 has two surfaces disposed oppositely along the Z direction. Since the first cavity 334, the second cavity 340 and the third cavity 336 are sealed by forming the first covering layer 338, the surface of the second cavity 340 away from the third cavity 336 has a convex shape towards a direction away from the third cavity 336.

In the first example of the present disclosure, the first cavity, the second cavity and the third cavity are connected. As such, not only can the manufacturing process difficulty and cost of the semiconductor device be reduced, but also the capacitive coupling effect between the adjacent gate lines and between the adjacent bit lines can be reduced, so as to improve the performance of the semiconductor device and facilitate the size shrinking of the semiconductor device in future.

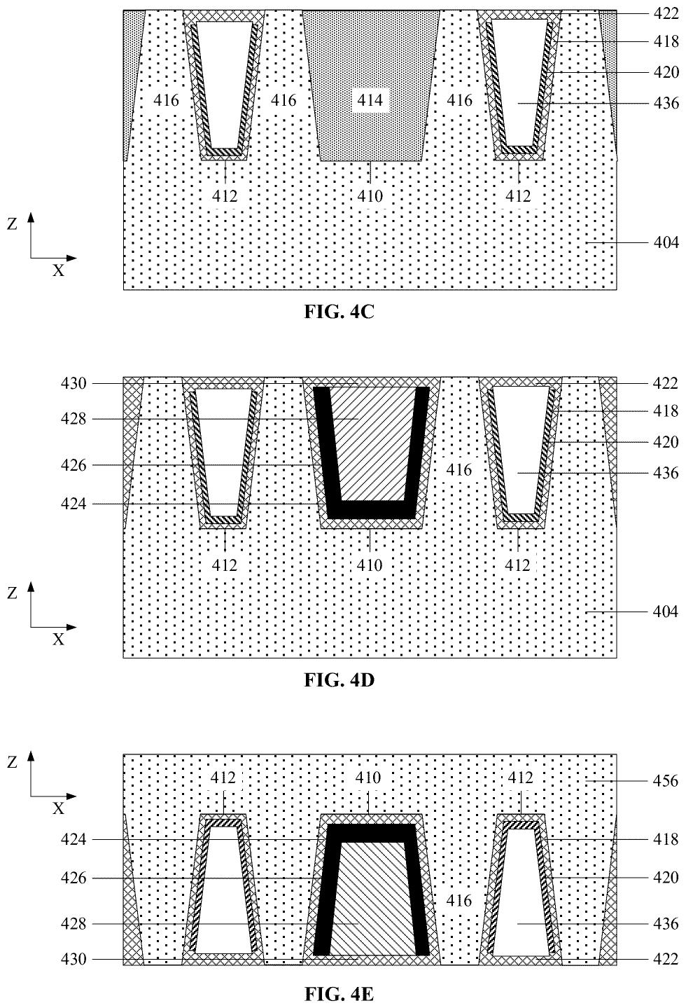

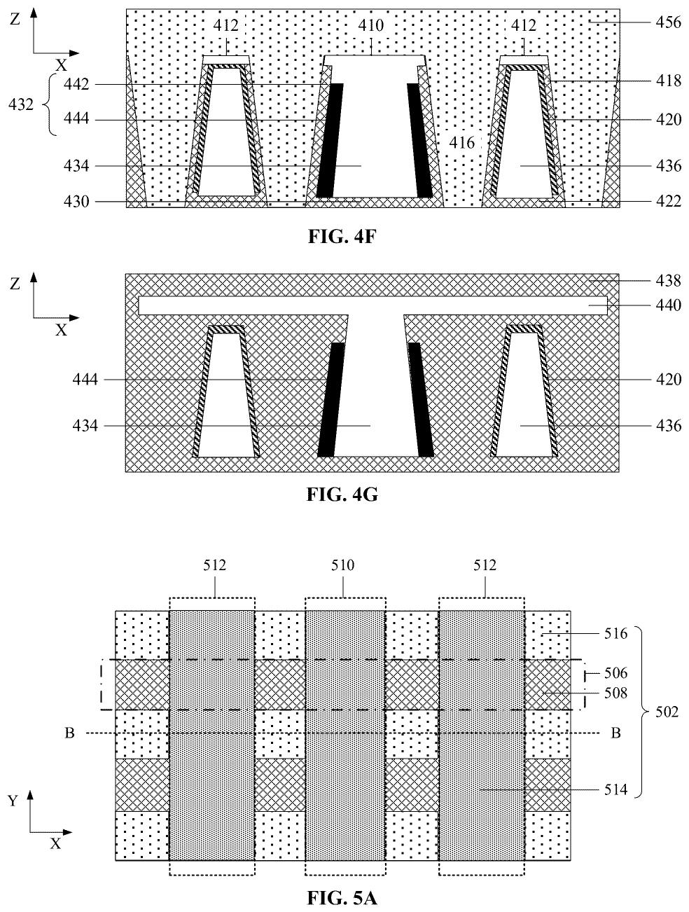

With reference to FIGS. 4A to 4G, FIGS. 4A to 4G are cross-sectional structural diagrams of a semiconductor device provided by a second example in a manufacturing process. The manufacturing process of the semiconductor device provided by the second example of the present disclosure will be illustrated in detail below in conjunction with FIGS. 4A to 4G.

FIG. 4A is an XY cross-sectional structural diagram of the semiconductor device, and FIG. 4B is an XZ cross-sectional structural diagram along a B-B cross-section in FIG. 4A. As shown in FIGS. 4A and 4B, a semiconductor structure 402 is provided and comprises a semiconductor layer 404; a plurality of first trenches 406 located in the semiconductor layer 404 and extending along an X direction; a first sacrificial layer 408 in the first trenches 406; a plurality of second trenches 410 and a plurality of fourth trenches 412 located in the semiconductor layer 404 and extending along a Y direction, wherein the second trenches 410 and the fourth trenches 412 are arranged alternately along the X direction; and a fourth sacrificial layer 414 in the second trenches 410 and the fourth trenches 412.

As shown in FIG. 4A, the first trench 406 extending along the X direction, the second trench 410 extending along the Y direction and the fourth trench 412 extending along the Y direction jointly divide the semiconductor layer 404 into a plurality of semiconductor pillars 416 arranged in an array along the X direction and the Y direction. In other words, the first sacrificial layer 408 extending along the X direction and the fourth sacrificial layer 414 extending along the Y direction jointly divide the semiconductor layer 404 into the plurality of semiconductor pillars 416 arranged in an array along the X direction and the Y direction.

FIGS. 4C to 4G are XZ cross-sectional structural diagrams along a cross-section parallel to the X direction. As shown in FIG. 4C, in some examples, the method further comprises: removing the fourth sacrificial layer 414 in the fourth trench 412; forming a second dielectric layer 418 covering a sidewall and bottom of the fourth trench 412; forming a blocking layer 420 covering the sidewall and the bottom of the fourth trench 412, wherein a surface of the blocking layer 420 is substantially flush with a surface of the semiconductor layer 404; removing part of the blocking layer 420 by back-etching, such that the surface of the blocking layer 420 is lower than the surface of the semiconductor layer 404; and forming a second covering layer 422 sealing the fourth trench 412 to form a third cavity 436 in the fourth trench 412.

Here, the second dielectric layer 418 covers the bottom and sidewall of the fourth trench 412; the blocking layer 420 covers the bottom and sidewall of the second dielectric layer 418, and covers the bottom and sidewall of the third cavity 436; and the second covering layer 422 covers the top of the third cavity 436. That is, the blocking layer 420 and the second covering layer 422 jointly surround and form the third cavity 436.

Here, the third cavity 436 has two surfaces disposed oppositely along the Z direction. Since the third cavity 436 is sealed by forming the second covering layer 422, the surface of the third cavity 436 away from the semiconductor layer 404 has a convex shape towards a direction away from the semiconductor layer 404.

Here, a material of the second dielectric layer 418 may include, but is not limited to, silicon oxide.

Here, in the present disclosure, there are no specific limitations to a material of the blocking layer 420 as long as the blocking layer 420 can be prevented from being removed to damage the morphology of the third cavity 436 during a backside process of the semiconductor layer.

Here, a material of the second covering layer 422 may include, but is not limited to, an insulation material, e.g., silicon oxide.

Here, a process of forming the second dielectric layer 418, the blocking layer 420 and the second covering layer 422 may include, but is not limited to, CVD, PVD or ALD, etc.

In the examples of the present disclosure, in S202, an initial gate structure 426 and a second sacrificial layer 428 filling the second trench 410 are formed in the second trench 410.

As shown in FIG. 4D, the fourth sacrificial layer 414 in the second trench 410 is removed. In some examples, in S202, the method further comprises: forming a first dielectric layer 424 covering a sidewall and bottom of the second trench 410; forming the initial gate structure 426 covering the sidewall and the bottom of the second trench 410; filling a sacrificial material in the second trench 410 to form the second sacrificial layer 428, wherein a surface of the initial gate structure 426, a surface of the second sacrificial layer 428 and a surface of the semiconductor layer 404 are substantially flush; removing part of the initial gate structure 426 and the second sacrificial layer 428 by back-etching, such that the surfaces of the initial gate structure 426 and the second sacrificial layer 428 are lower than the surface of the semiconductor layer 404; filling a dielectric material in the second trench 410 to form a fourth dielectric material layer covering the surface of the semiconductor layer 404; and planarizing the fourth dielectric material layer to form a fourth dielectric layer 430 exposing the surface of the semiconductor layer 404, wherein a surface of the fourth dielectric layer 430 is substantially flush with the surface of the semiconductor layer 404.

Here, the first dielectric layer 424 and the initial gate structure 426 cover the bottom and sidewall of the second sacrificial layer 428, and the fourth dielectric layer 430 covers the top of the second sacrificial layer 428. The second sacrificial layer 428 will be removed during a subsequent process to form the first cavity, so as to reduce the capacitive coupling effect between the two adjacent gate lines.

In the examples of the present disclosure, in S203, part of the semiconductor layer 404 is removed to expose the first sacrificial layer 408.

As shown in FIG. 4E, the back side of the semiconductor layer 404 is thinned to expose the first sacrificial layer 408. Since the height of the first sacrificial layer 408 along the Z direction is greater than the height of the fourth sacrificial layer 414 along the Z direction, the remaining semiconductor layer forms the bit lines 456 while removing part of the semiconductor layer 404 to expose the first sacrificial layer 408. The plurality of bit lines 456 are spaced apart along the Y direction, and the bit lines 456 extending along the X direction are connected with the plurality of semiconductor pillars 416 spaced apart along the X direction.

Here, the semiconductor pillar 416 comprises, along the Z direction, a source, a drain and a channel region between the source and the drain, wherein each bit line may be connected with the plurality of sources or drains arranged along the X direction; and correspondingly, the memory capacitor may be connected with the source or the drain.

In the examples of the present disclosure, in S204, the first sacrificial layer 408 is etched to form a plurality of third trenches extending along the X direction and arranged along the Y direction.

Here, part of the first sacrificial layer 408 may be removed from the back side of the semiconductor layer 404 to form the plurality of third trenches extending along the X direction and arranged along the Y direction, wherein the third trench is located between the two adjacent bit lines 456 along the Y direction.

In the examples of the present disclosure, in S205, part of the initial gate structure 426 and the second sacrificial layer 428 in the second trench 410 are removed through the third trench to divide one initial gate structure 426 into two gate structures 432 and to form the first cavity 434.

As shown in FIG. 4F, the first dielectric layer 424 covering the bottom of the second trench 410 is removed through the third trench to expose the initial gate structure 426 covering the bottom of the second trench 410. At this point, the first dielectric layer 424 covering the two oppositely disposed sidewalls of the second trench 410 forms a gate dielectric layer 442. The initial gate structure 426 covering the bottom of the second trench 410 is removed through the third trench to divide one initial gate structure 426 into two gate layers 444, that is, the initial gate structure 426 covering the two oppositely disposed sidewalls of the second trench 410 forms the gate layers 444, wherein the gate dielectric layer 442 covering the sidewall of the semiconductor pillar 416 and the gate layer 444 covering the gate dielectric layer 442 jointly form the gate structure 432. In addition, the second sacrificial layer 428 in the second trench 410 is removed through the third trench to form the first cavity 434.

Here, the gate structure 432 is located on a sidewall of the semiconductor pillar 416, and the gate structures 432 of the plurality of semiconductor pillars arranged along the Y direction are connected to form a gate line. Two gate lines in the same second trench 410 form a gate line group that is located between the two adjacent semiconductor pillars 416 along the X direction, and each gate line group comprises two gate lines spaced apart along the X direction and extending along the Y direction.

Here, the first cavity 434 is located between the two gate lines in the same gate line group, and the first cavity 434 extends along the Y direction.

Here, the blocking layer 420 in the fourth trench 412 may prevent a process of forming the first cavity 434 from damaging the morphology of the third cavity 436. As such, the blocking layer 420 may serve as an etch stop layer.

In the examples of the present disclosure, in S206, a first covering layer 438 sealing the third trench is formed to form a second cavity 440 in the third trench, wherein the first cavity 434 and the second cavity 440 are connected.

As shown in FIG. 4G, the first covering layer 438 sealing the third trench is formed to form the second cavity 440 in the third trench, wherein the first cavity 434 and the second cavity 440 are connected, the first cavity 434 and the third cavity 436 are not connected, and the second cavity 440 and the third cavity 436 are not connected.

Here, the second cavity 440 is located between the two adjacent bit lines 456 along the Y direction and extends along the X direction.

Here, a material of the first covering layer 438 may include, but is not limited to, an insulation material, e.g., silicon oxide.

Here, the second cavity 440 has two surfaces disposed oppositely along the Z direction. Since the first cavity 434 and the second cavity 440 are sealed by forming the first covering layer 438, the surface of the second cavity 440 away from the first cavity 434 has a convex shape towards a direction away from the first cavity 434.

In the second example of the present disclosure, the first cavity and the second cavity are connected, the first cavity and the third cavity are not connected, and the second cavity and the third cavity are not connected. As such, not only can the manufacturing process difficulty and cost of the semiconductor device be reduced, but also the capacitive coupling effect between the adjacent gate lines and between the adjacent bit lines can be reduced, so as to improve the performance of the semiconductor device and facilitate the size shrinking of the semiconductor device in future.

In the examples of the present disclosure, the second cavity is disposed between the two adjacent bit lines, and the third cavity is disposed between the two adjacent gate line groups. In the third example of the present disclosure, the second cavity and the third cavity are connected. In the fourth example of the present disclosure, the second cavity and the third cavity are not connected.

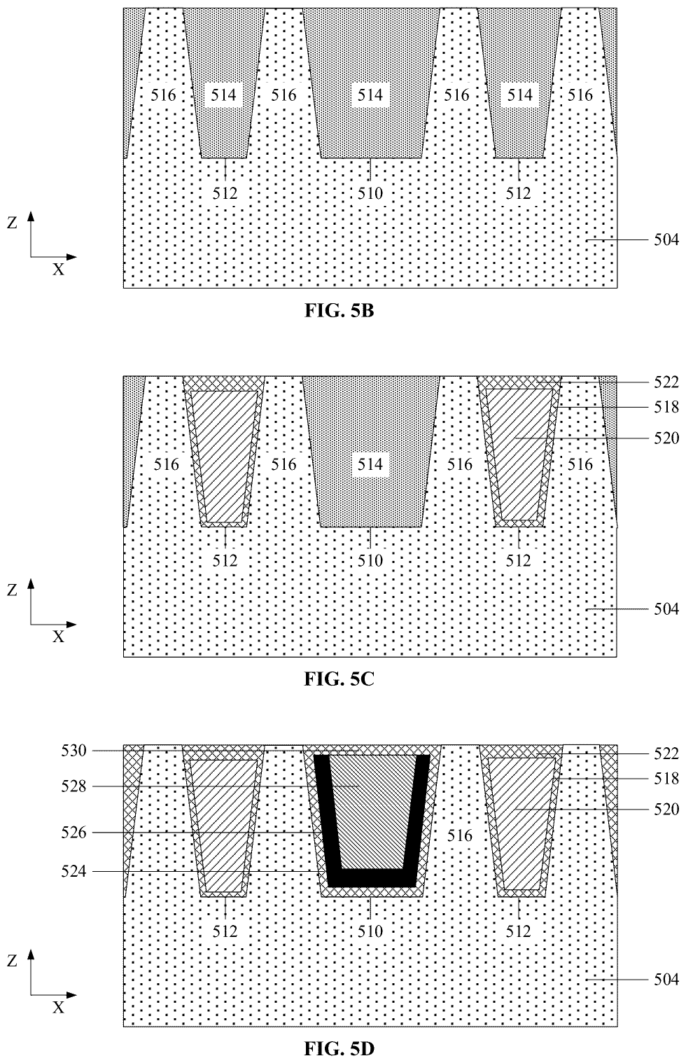

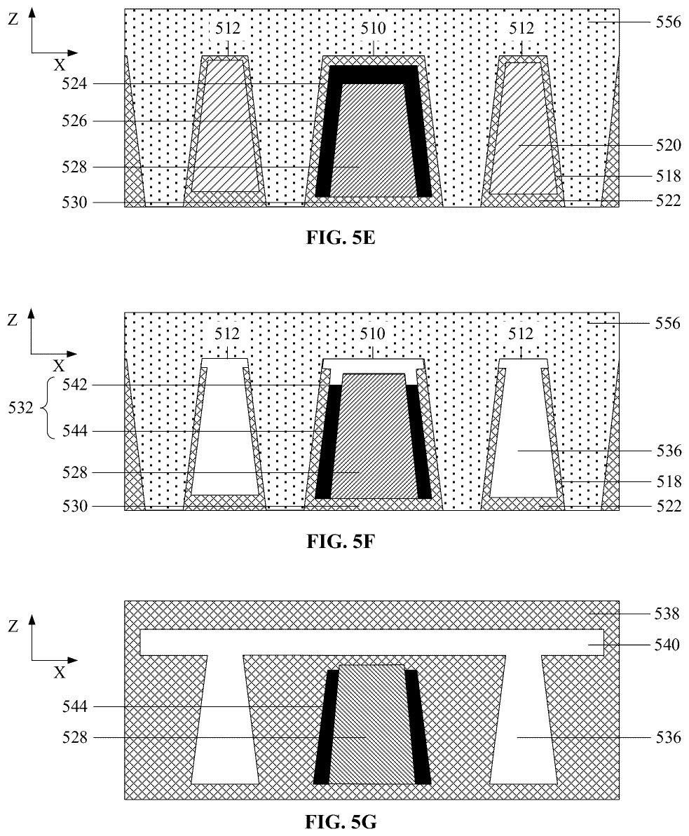

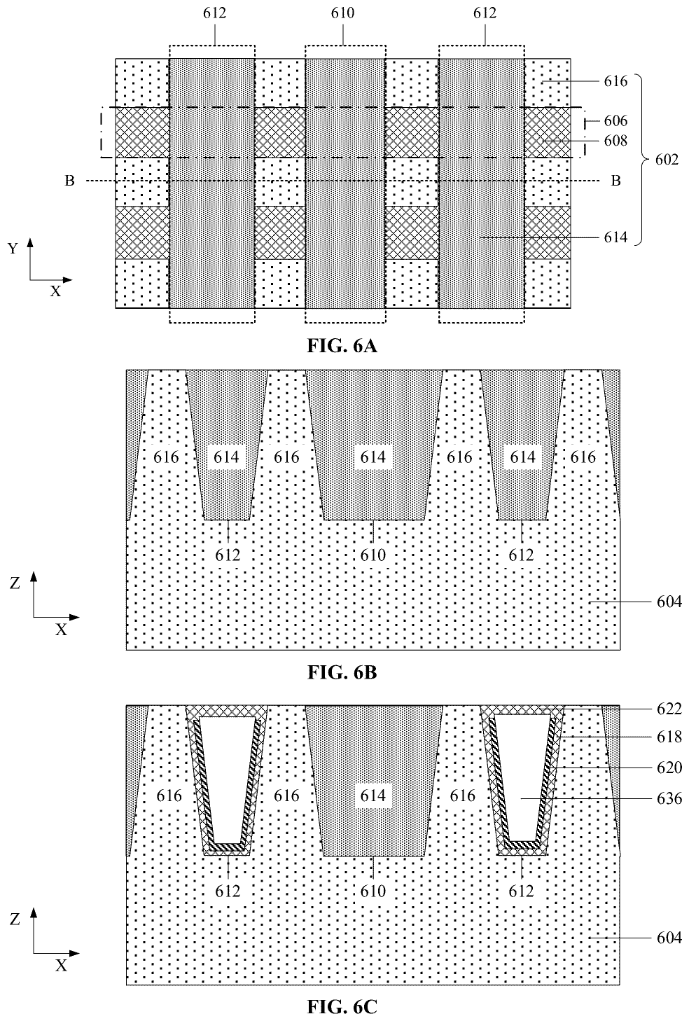

With reference to FIGS. 5A to 5G, FIGS. 5A to 5G are cross-sectional structural diagrams of a semiconductor device provided by a third example in a manufacturing process. The manufacturing process of the semiconductor device provided by the third example of the present disclosure will be illustrated in detail below in conjunction with FIGS. 5A to 5G.

FIG. 5A is an XY cross-sectional structural diagram of the semiconductor device, and FIG. 5B is an XZ cross-sectional structural diagram along a B-B cross-section in FIG. 5A. As shown in FIGS. 5A and 5B, a semiconductor structure 502 is provided and comprises a semiconductor layer 504; a plurality of first trenches 506 located in the semiconductor layer 504 and extending along an X direction; a first sacrificial layer 508 in the first trenches 506; a plurality of second trenches 510 and a plurality of fourth trenches 512 located in the semiconductor layer 504 and extending along a Y direction, wherein the second trenches 510 and the fourth trenches 512 are arranged alternately along the X direction; and a fourth sacrificial layer 514 in the second trenches 510 and the fourth trenches 512.

As shown in FIG. 5A, the first trench 506 extending along the X direction, the second trench 510 extending along the Y direction and the fourth trench 512 extending along the Y direction jointly divide the semiconductor layer 504 into a plurality of semiconductor pillars 516 arranged in an array along the X direction and the Y direction. In other words, the first sacrificial layer 508 extending along the X direction and the fourth sacrificial layer 514 extending along the Y direction jointly divide the semiconductor layer 504 into the plurality of semiconductor pillars 516 arranged in an array along the X direction and the Y direction.

FIGS. 5C to 5G are XZ cross-sectional structural diagrams along a cross-section parallel to the X direction. As shown in FIG. 5C, in some examples, the method further comprises: removing a fourth sacrificial layer 514 in the fourth trench 512; forming a second dielectric layer 518 covering a sidewall and bottom of the fourth trench 512; filling a sacrificial material in the fourth trench 512 to form a third sacrificial layer 520, wherein a surface of the third sacrificial layer 520 is substantially flush with a surface of the semiconductor layer 504; removing part of the third sacrificial layer 520 by back-etching, such that the surface of the third sacrificial layer 520 is lower than the surface of the semiconductor layer 504; filling a dielectric material in the fourth trench 512 to form a third dielectric material layer covering the surface of the semiconductor layer 504; and planarizing the third dielectric material layer to form a third dielectric layer 522 exposing the surface of the semiconductor layer 504, wherein the surface of the third dielectric layer 522 is substantially flush with the surface of the semiconductor layer 504.

Here, the second dielectric layer 518 covers the bottom and sidewall of the third sacrificial layer 520, and the third dielectric layer 522 covers the top of the third sacrificial layer 520. The third sacrificial layer 520 will be removed during a subsequent process to form the third cavity, so as to reduce the capacitive coupling effect between two adjacent gate line groups (or two adjacent gate lines).

As shown in FIG. 5D, the fourth sacrificial layer 514 in the second trench 510 is removed; a first dielectric layer 524 covering a sidewall and bottom of the second trench 510 is formed; an initial gate structure 526 covering the sidewall and the bottom of the second trench 510 is formed; a dielectric material is filled in the second trench 510 to form a fifth dielectric layer 528, such that a surface of the initial gate structure 526, a surface of the fifth dielectric layer 528 and the surface of the semiconductor layer 504 are substantially flush; part of the initial gate structure 526 and the fifth dielectric layer 528 are removed by back-etching, such that the surfaces of the initial gate structure 526 and the fifth dielectric layer 528 are lower than the surface of the semiconductor layer 504; a dielectric material is filled in the second trench 510 to form a sixth dielectric material layer covering the surface of the semiconductor layer 504; the sixth dielectric material layer is planarized to form a sixth dielectric layer 530 exposing the surface of the semiconductor layer 504, such that a surface of the sixth dielectric layer 530 is substantially flush with the surface of the semiconductor layer 504.

Here, the first dielectric layer 524 (or the initial gate structure 526) covers the bottom and sidewall of the fifth dielectric layer 528, and the sixth dielectric layer 530 covers the top of the fifth dielectric layer 528.

As shown in FIG. 5E, the back side of the semiconductor layer 504 is thinned to expose the first sacrificial layer 508. Since the height of the first sacrificial layer 508 along the Z direction is greater than the height of the fourth sacrificial layer 514 along the Z direction, the remaining semiconductor layer forms the bit lines 556 while removing part of the semiconductor layer 504 to expose the first sacrificial layer 508. The plurality of bit lines 556 are spaced apart along the Y direction, and the bit lines 556 extending along the X direction are connected with the plurality of semiconductor pillars 516 spaced apart along the X direction.

Here, the semiconductor pillar 516 comprises, along the Z direction, a source, a drain and a channel region between the source and the drain, wherein each bit line may be connected with the plurality of sources or drains arranged along the X direction; and correspondingly, the memory capacitor may be connected with the source or the drain.

Here, part of the first sacrificial layer 508 may be removed from the back side of the semiconductor layer 504 to form the plurality of third trenches extending along the X direction and arranged along the Y direction, wherein the third trench is located between the two adjacent bit lines 556 along the Y direction.

As shown in FIG. 5F, the first dielectric layer 524 covering the bottom of the second trench 510 is removed through the third trench to expose the initial gate structure 526 covering the bottom of the second trench 510. At this point, the first dielectric layer 524 covering the two oppositely disposed sidewalls of the second trench 510 forms a gate dielectric layer 542. The initial gate structure 526 covering the bottom of the second trench 510 is removed through the third trench to divide one initial gate structure 526 into two gate layers 544, that is, the initial gate structure 526 covering the two oppositely disposed sidewalls of the second trench 510 forms the gate layers 544, wherein the gate dielectric layer 542 covering the sidewall of the semiconductor pillar 516 and the gate layer 544 covering the gate dielectric layer 542 jointly form the gate structure 532.

Here, the gate structure 532 is located on a sidewall of the semiconductor pillar 516, and the gate structures 532 of the plurality of semiconductor pillars arranged along the Y direction are connected to form a gate line. Two gate lines in the same second trench 510 form a gate line group that is located between the two adjacent semiconductor pillars 516 along the X direction, and each gate line group comprises two gate lines spaced apart along the X direction and extending along the Y direction, and the two gate lines are isolated by the fifth dielectric layer 528.

As shown in FIG. 5F, the second dielectric layer 518 covering the bottom of the fourth trench 512 is removed through the third trench to expose the third sacrificial layer 520 covering the bottom of the fourth trench 512; and the third sacrificial layer 520 in the fourth trench 512 is removed through the third trench to form the third cavity 536.

Here, the third cavity 536 is located between the two adjacent semiconductor pillars 516 along the X direction, or the third cavity 536 is located between the two adjacent gate line groups along the X direction and extends along the Y direction.

Here, the third cavity 536 has two surfaces disposed oppositely along the Z direction. Since the third cavity 536 is formed by removing the third sacrificial layer 520, the surface of the third cavity 536 away from the bit line 556 is a flat surface, that is, a surface of the third dielectric layer 522 close to the third cavity 536 is a flat surface.

As shown in FIG. 5G, a first covering layer 538 sealing the third trench is formed to form a second cavity 540 in the third trench, wherein the second cavity 540 and the third cavity 536 are connected.

Here, the second cavity 540 is located between the two adjacent bit lines 556 along the Y direction and extends along the X direction.

Here, the second cavity 540 has two surfaces disposed oppositely along the Z direction. Since the second cavity 540 and the third cavity 536 are sealed by forming the first covering layer 538, the surface of the second cavity 540 away from the third cavity 536 has a convex shape towards a direction away from the third cavity 536.

In the third example of the present disclosure, the second cavity and the third cavity are connected. As such, not only can the manufacturing process difficulty and cost of the semiconductor device be reduced, but also the capacitive coupling effect between the adjacent gate line groups and between the adjacent bit lines can be reduced, so as to improve the performance of the semiconductor device and facilitate the size shrinking of the semiconductor device in future.

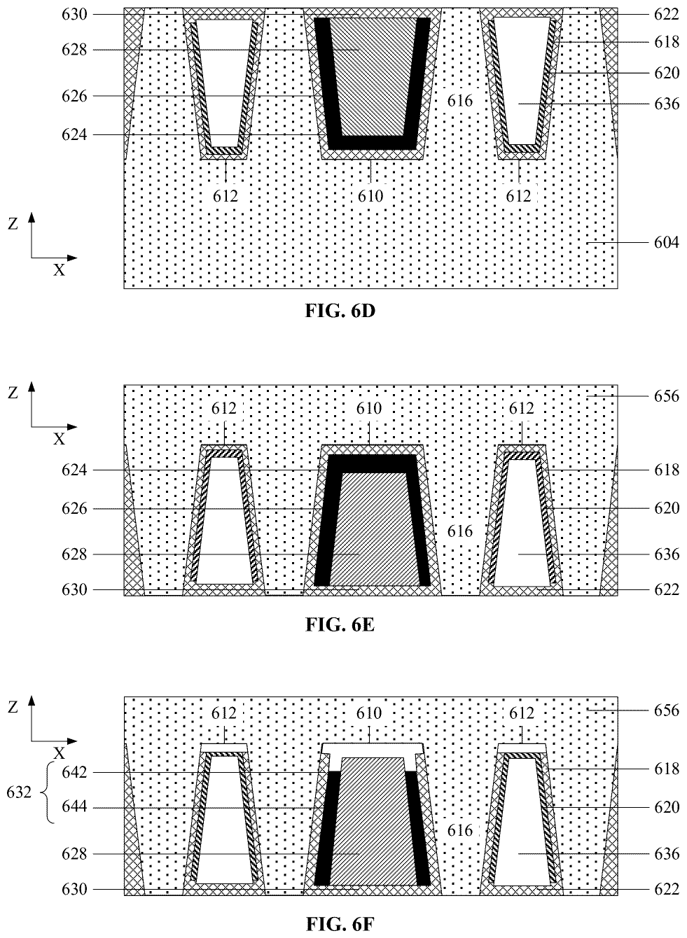

With reference to FIGS. 6A to 6G, FIGS. 6A to 6G are cross-sectional structural diagrams of a semiconductor device provided by a fourth example in a manufacturing process. The manufacturing process of the semiconductor device provided by the fourth example of the present disclosure will be illustrated in detail below in conjunction with FIGS. 6A to 6G.

FIG. 6A is an XY cross-sectional structural diagram of the semiconductor device, and FIG. 6B is an XZ cross-sectional structural diagram along a B-B cross-section in FIG. 6A. As shown in FIGS. 6A and 6B, a semiconductor structure 602 is provided and comprises a semiconductor layer 604; a plurality of first trenches 606 located in the semiconductor layer 604 and extending along an X direction; a first sacrificial layer 608 in the first trenches 606; a plurality of second trenches 610 and a plurality of fourth trenches 612 located in the semiconductor layer 604 and extending along a Y direction, wherein the second trenches 610 and the fourth trenches 612 are arranged alternately along the X direction; and a fourth sacrificial layer 614 in the second trenches 610 and the fourth trenches 612.

As shown in FIG. 6A, the first trench 606 extending along the X direction, the second trench 610 extending along the Y direction and the fourth trench 612 extending along the Y direction jointly divide the semiconductor layer 604 into a plurality of semiconductor pillars 616 arranged in an array along the X direction and the Y direction. In other words, the first sacrificial layer 608 extending along the X direction and the fourth sacrificial layer 614 extending along the Y direction jointly divide the semiconductor layer 604 into the plurality of semiconductor pillars 616 arranged in an array along the X direction and the Y direction.

FIGS. 6C to 6G are XZ cross-sectional structural diagrams along a cross-section parallel to the X direction. As shown in FIG. 6C, the fourth sacrificial layer 614 in the fourth trench 612 is removed; a second dielectric layer 618 covering a sidewall and bottom of the fourth trench 612 is formed; a blocking layer 620 covering the sidewall and the bottom of the fourth trench 612 is formed, wherein a surface of the blocking layer 620 is substantially flush with a surface of the semiconductor layer 604; part of the blocking layer 620 is removed by back-etching, such that the surface of the blocking layer 620 is lower than the surface of the semiconductor layer 604; and a second covering layer 622 sealing the fourth trench 612 is formed to form a third cavity 636 in the fourth trench 612.

Here, the second dielectric layer 618 covers the bottom and sidewall of the fourth trench 612; the blocking layer 620 covers the bottom and sidewall of the second dielectric layer 618, and covers the bottom and sidewall of the third cavity 636; and the second covering layer 622 covers the top of the third cavity 636. That is, the blocking layer 620 and the second covering layer 622 jointly surround and form the third cavity 636.

Here, the third cavity 636 has two surfaces disposed oppositely along the Z direction. Since the third cavity 636 is sealed by forming the second covering layer 622, the surface of the third cavity 636 away from the semiconductor layer 604 has a convex shape towards a direction away from the semiconductor layer 604.

As shown in FIG. 6D, the fourth sacrificial layer 614 in the second trench 610 is removed; a first dielectric layer 624 covering a sidewall and bottom of the second trench 610 is formed; an initial gate structure 626 covering the sidewall and the bottom of the second trench 610 is formed; a dielectric material is filled in the second trench 610 to form a fifth dielectric layer 628, such that a surface of the initial gate structure 626, a surface of the fifth dielectric layer 628 and the surface of the semiconductor layer 604 are substantially flush; part of the initial gate structure 626 and the fifth dielectric layer 628 are removed by back-etching, such that the surfaces of the initial gate structure 626 and the fifth dielectric layer 628 are lower than the surface of the semiconductor layer 604; a dielectric material is filled in the second trench 610 to form a sixth dielectric material layer covering the surface of the semiconductor layer 604; the sixth dielectric material layer is planarized to form a sixth dielectric layer 630 exposing the surface of the semiconductor layer 604, such that a surface of the sixth dielectric layer 630 is substantially flush with the surface of the semiconductor layer 604.

Here, the first dielectric layer 624 and the initial gate structure 626 cover the bottom and sidewall of the fifth dielectric layer 628, and the sixth dielectric layer 630 covers the top of the fifth dielectric layer 628.

As shown in FIG. 6E, the back side of the semiconductor layer 604 is thinned to expose the first sacrificial layer 608. Since the height of the first sacrificial layer 608 along the Z direction is greater than the height of the fourth sacrificial layer 614 along the Z direction, the remaining semiconductor layer forms the bit lines 656 while removing part of the semiconductor layer 604 to expose the first sacrificial layer 608. The plurality of bit lines 656 are spaced apart along the Y direction, and the bit lines 656 extending along the X direction are connected with the plurality of semiconductor pillars 616 spaced apart along the X direction.

Here, the semiconductor pillar 616 comprises, along the Z direction, a source, a drain and a channel region between the source and the drain, wherein each bit line may be connected with the plurality of sources or drains arranged along the X direction; and correspondingly, the memory capacitor may be connected with the source or the drain.

Here, part of the first sacrificial layer 608 may be removed from the back side of the semiconductor layer 604 to form the plurality of third trenches extending along the X direction and arranged along the Y direction, wherein the third trench is located between the two adjacent bit lines 656 along the Y direction.

As shown in FIG. 6F, the first dielectric layer 624 covering the bottom of the second trench 610 is removed through the third trench to expose the initial gate structure 626 covering the bottom of the second trench 610. At this point, the first dielectric layer 624 covering the two oppositely disposed sidewalls of the second trench 610 forms a gate dielectric layer 642. The initial gate structure 626 covering the bottom of the second trench 610 is removed through the third trench to divide one initial gate structure 626 into two gate layers 644, that is, the initial gate structure 626 covering the two oppositely disposed sidewalls of the second trench 610 forms the gate layers 644, wherein the gate dielectric layer 642 covering the sidewall of the semiconductor pillar 616 and the gate layer 644 covering the gate dielectric layer 642 jointly form the gate structure 632.

Here, the gate structure 632 is located on a sidewall of the semiconductor pillar 616, and the gate structures 632 of the plurality of semiconductor pillars arranged along the Y direction are connected to form a gate line. Two gate lines in the same second trench 610 form a gate line group that is located between the two adjacent semiconductor pillars 616 along the X direction, each gate line group comprises two gate lines spaced apart along the X direction and extending along the Y direction, and the two gate lines are isolated by the fifth dielectric layer 628.

Here, the blocking layer 620 in the fourth trench 612 may prevent a process of forming the gate structure 632 from damaging the morphology of the third cavity 636. As such, the blocking layer 620 may serve as an etch stop layer.

As shown in FIG. 6G, a first covering layer 638 sealing the third trench is formed to form a second cavity 640 in the third trench, wherein the second cavity 640 and the third cavity 636 are not connected.

Here, the second cavity 640 is located between the two adjacent bit lines 656 along the Y direction and extends along the X direction.

Here, the second cavity 640 has two surfaces disposed oppositely along the Z direction. Since the second cavity 640 is sealed by forming the first covering layer 638, the surface of the second cavity 640 away from the third cavity 636 has a convex shape towards a direction away from the third cavity 636.

In the fourth example of the present disclosure, the second cavity and the third cavity are not connected. As such, not only can the manufacturing process difficulty and cost of the semiconductor device be reduced, but also the capacitive coupling effect between the adjacent gate line groups and between the adjacent bit lines can be reduced, so as to improve the performance of the semiconductor device and facilitate the size shrinking of the semiconductor device in future.

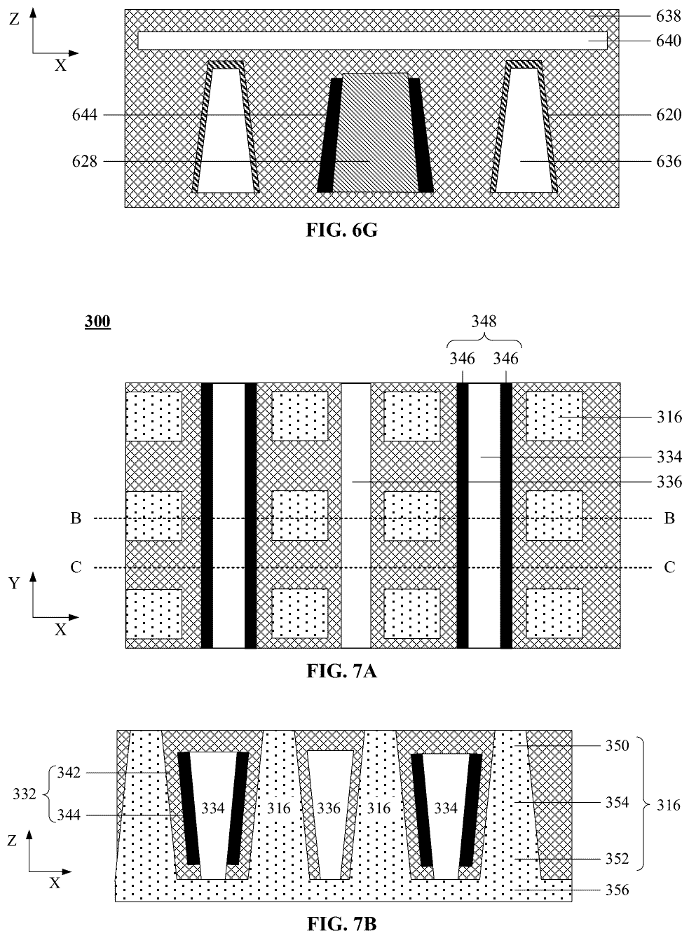

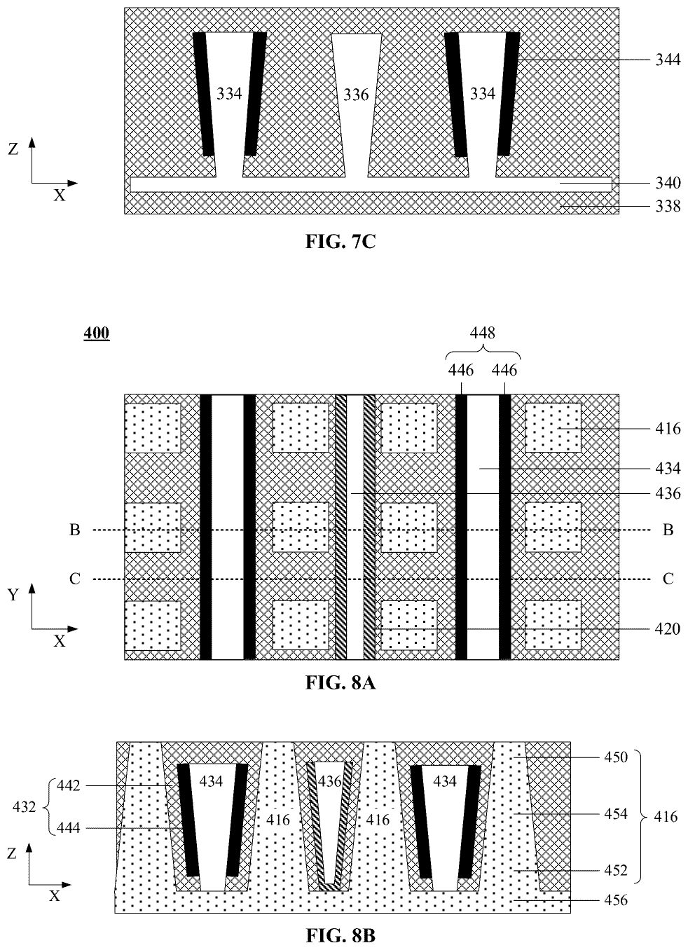

With reference to FIGS. 7A to 7C, FIGS. 7A to 7C are cross-sectional structural diagrams of a semiconductor device provided by a first example. FIG. 7A is an XY cross-sectional structural diagram of a semiconductor device provided by a first example, FIG. 7B is an XZ cross-sectional structural diagram along a B-B cross-section in FIG. 7A, and FIG. 7C is an XZ cross-sectional structural diagram along a C-C cross-section in FIG. 7A.

As shown in FIGS. 7A to 7C, examples of the present disclosure provide a semiconductor device. The semiconductor device 300 comprises: a plurality of semiconductor pillars 316 arranged along an X direction and a Y direction, wherein the X direction intersects the Y direction; a plurality of gate lines 346 spaced apart along the X direction, wherein each gate line 346 extends along the Y direction and is connected with the plurality of semiconductor pillars 316 arranged along the Y direction; a first cavity 334 located between the two adjacent ones of the plurality of gate lines 346 along the X direction and extending along the Y direction; a plurality of bit lines 356 spaced apart along the Y direction, wherein each bit line 356 extends along the X direction and is connected with the plurality of semiconductor pillars 316 arranged along the X direction; and a second cavity 340 located between two adjacent ones of the plurality of bit lines 356 along the Y direction and extending along the X direction, wherein the second cavity 340 and the first cavity 334 are connected.

As shown in FIG. 7A, in some examples, the plurality of gate lines 346 comprises a plurality of gate line groups 348 spaced apart along the X direction, wherein each gate line group 348 comprises two gate lines 346 spaced apart along the X direction, and is located between two adjacent ones of the semiconductor pillars 316 along the X direction, and the first cavity 334 is located between the two gate lines 346 in the same gate line group 348.

As shown in FIGS. 7A and 7C, in some examples, the semiconductor device 300 further comprises a third cavity 336 located between the two adjacent gate line groups 348 along the X direction and extending along the Y direction, wherein the third cavity 336 is located between the two adjacent ones of the semiconductor pillars 316 along the X direction, and the first cavity 334, the second cavity 340 and the third cavity 336 are connected.

As shown in FIG. 7B, in some examples, each semiconductor pillar 316 extends along a Z direction that is perpendicular to a plane formed by the X direction and the Y direction; the third cavity 336 has two opposite surfaces along the Z direction, and the surface of the third cavity 336 away from the second cavity 340 is a flat surface.

As shown in FIG. 7B, in some examples, the semiconductor pillar 316 comprises, along the Z direction, a source 350, a drain 352 and a channel region 354 between the source 350 and the drain 352; and the semiconductor device 300 further comprises a gate structure 332 on at least a sidewall of the semiconductor pillar 316, wherein the gate structures 332 of the plurality of semiconductor pillars 316 arranged along the Y direction are connected to form a gate line 346.

Here, the gate structure 332 comprises a gate dielectric layer 342 covering a sidewall of the semiconductor pillar 316 and a gate layer 344 covering the gate dielectric layer 342.

As shown in FIG. 7B, in some examples, the bit line 356 is connected with the plurality of drains 352 or sources 350 arranged along the X direction, and the semiconductor device 300 further comprises a memory capacitor connected with the source 350 or the drain 352. FIG. 7B illustrates that the bit line 356 is connected with the plurality of drains 352 arranged along the X direction.

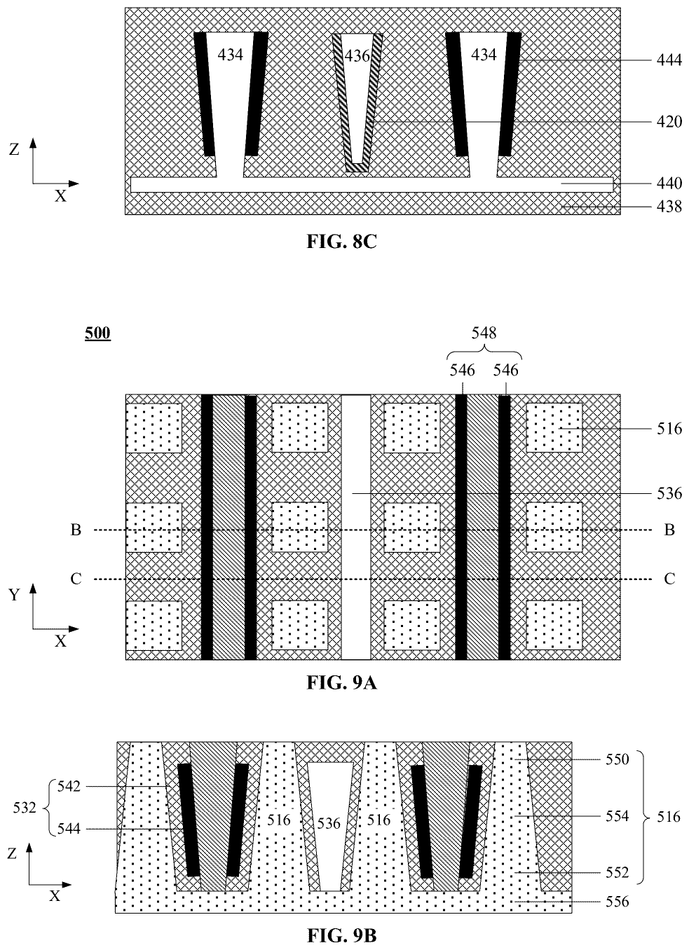

With reference to FIGS. 8A to 8C, FIGS. 8A to 8C are cross-sectional structural diagrams of a semiconductor device provided by a second example. FIG. 8A is an XY cross-sectional structural diagram of a semiconductor device provided by a second example, FIG. 8B is an XZ cross-sectional structural diagram along a B-B cross-section in FIG. 8A, and FIG. 8C is an XZ cross-sectional structural diagram along a C-C cross-section in FIG. 8A.

As shown in FIGS. 8A to 8C, in some examples, the semiconductor device 400 further comprises: a third cavity 436 located between two adjacent ones of the gate line groups 448 along the X direction and extending along the Y direction, wherein the third cavity 436 is located between two adjacent ones of the semiconductor pillars 416 along the X direction, and the second cavity 440 and the third cavity 436 are not connected; and a blocking layer 420 at least covering part of the third cavity 436, wherein at least part of the blocking layer 420 is located between the semiconductor pillar 416 and the third cavity 436, and at least part of the blocking layer 420 is located between the second cavity 440 and the third cavity 436.

As shown in FIG. 8C, in some examples, the semiconductor pillar 416 extends along a Z direction that is perpendicular to a plane formed by the X direction and the Y direction, the third cavity 436 has two opposite surfaces along the Z direction, and the surface of the third cavity 436 away from the second cavity 440 has a convex shape towards a direction away from the second cavity 440.

Here, each gate line group 448 comprises two gate lines 446 extending along the Y direction. A first cavity 434 is disposed between the two gate lines 446 in the same gate line group 448.

Here, the gate structure 432 comprises a gate dielectric layer 442 covering a sidewall of the semiconductor pillar 416 and a gate layer 444 covering the gate dielectric layer 442.

Here, the semiconductor pillar 416 comprises, along the Z direction, a source 450, a drain 452 and a channel region 454 between the source 450 and the drain 452. The semiconductor device 400 comprises a bit line 356 connected with the plurality of drains 352 arranged along the X direction, and a memory capacitor connected with the source 350.

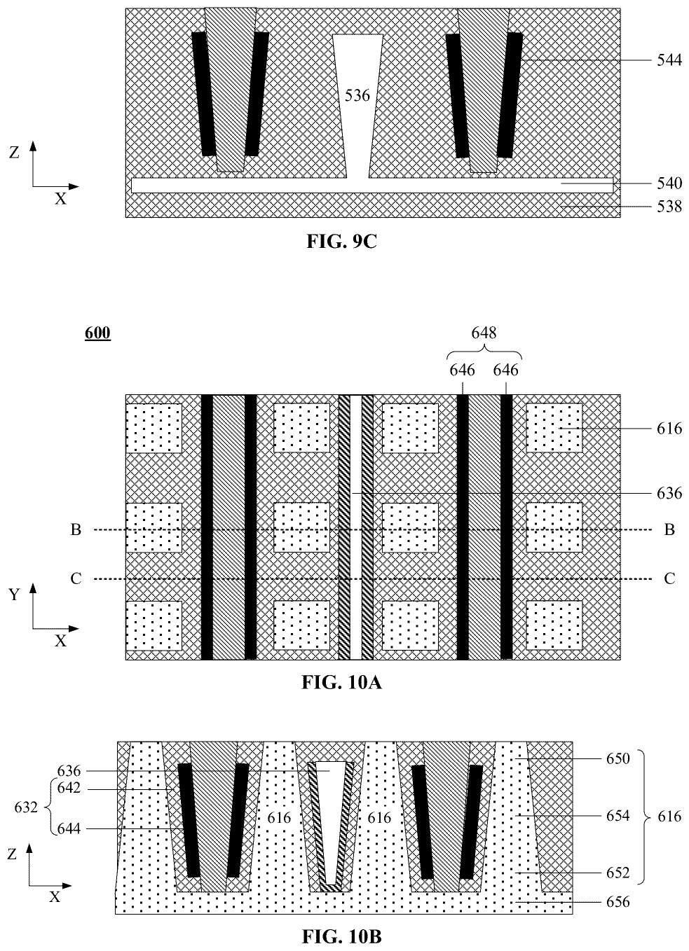

With reference to FIGS. 9A to 9C, FIGS. 9A to 9C are cross-sectional structural diagrams of a semiconductor device provided by a third example. FIG. 9A is an XY cross-sectional structural diagram of a semiconductor device provided by a third example, FIG. 9B is an XZ cross-sectional structural diagram along a B-B cross-section in FIG. 9A, and FIG. 9C is an XZ cross-sectional structural diagram along a C-C cross-section in FIG. 9A.

As shown in FIGS. 9A to 9C, examples of the present disclosure provide a semiconductor device. The semiconductor device 500 comprises: a plurality of semiconductor pillars 516 arranged along an X direction and a Y direction, wherein the X direction intersects the Y direction; a plurality of gate line groups 548 spaced apart along the X direction, wherein each of the plurality of gate line groups 548 comprises two gate lines 546 spaced apart along the X direction, and is located between the two adjacent ones of the plurality of semiconductor pillars 516 along the X direction, and each gate line 546 extends along the Y direction and is connected with the plurality of semiconductor pillars 516 arranged along the Y direction; a third cavity 536 located between two adjacent ones of the plurality of gate line groups 548 along the X direction and extending along the Y direction; a plurality of bit lines 556 spaced apart along the Y direction, wherein each bit line 556 extends along the X direction and is connected with the plurality of semiconductor pillars 516 arranged along the X direction; and a second cavity 540 located between two adjacent ones of the bit lines 556 along the Y direction and extending along the X direction.

As shown in FIGS. 9A and 9C, in some examples, the third cavity 536 is located between the two adjacent ones of the semiconductor pillars 516 along the X direction, and the second cavity 540 and the third cavity 536 are connected.

As shown in FIG. 9B, in some examples, each semiconductor pillar 516 extends along a Z direction that is perpendicular to a plane formed by the X direction and the Y direction; the third cavity 536 has two opposite surfaces along the Z direction, and the surface of the third cavity 536 away from the second cavity 540 is a flat surface.

As shown in FIGS. 9A and 9B, in some examples, the semiconductor pillar 516 comprises, along the Z direction, a source 550, a drain 552 and a channel region 554 between the source 550 and the drain 552, and the semiconductor device 500 further comprises a gate structure 532 on at least a sidewall of the semiconductor pillar 516, wherein the gate structures 532 of the plurality of semiconductor pillars 516 arranged along the Y direction are connected to form a gate line 546.

Here, the gate structure 532 comprises a gate dielectric layer 542 covering the sidewall of the semiconductor pillar 516 and a gate layer 544 covering the gate dielectric layer 542.

As shown in FIG. 9B, in some examples, the bit line 556 is connected with the plurality of drains 552 or sources 550 arranged along the X direction, and the semiconductor device 500 further comprises a memory capacitor connected with the source 550 or the drain 552. FIG. 9B illustrates that the bit line 556 is connected with the plurality of drains 552 arranged along the X direction.

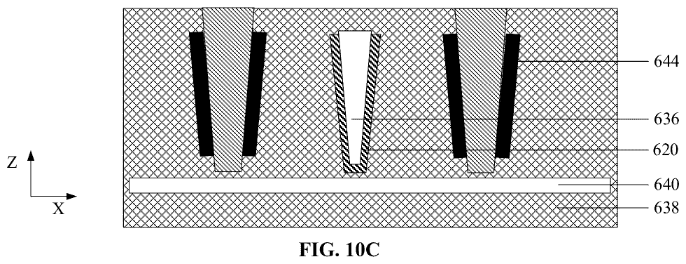

With reference to FIGS. 10A to 10C, FIGS. 10A to 10C are cross-sectional structural diagrams of a semiconductor device provided by a fourth example. FIG. 10A is an XY cross-sectional structural diagram of a semiconductor device provided by a fourth example, FIG. 10B is an XZ cross-sectional structural diagram along a B-B cross-section in FIG. 10A, and FIG. 10C is an XZ cross-sectional structural diagram along a C-C cross-section in FIG. 10A.

As shown in FIGS. 10A to 10C, in some examples, the third cavity 636 is located between two adjacent ones of the semiconductor pillars 616 along the X direction, and the second cavity 640 and the third cavity 636 are not connected; and the semiconductor device 600 further comprises a blocking layer 620 at least covering part of the third cavity 636, wherein at least part of the blocking layer 620 is located between the semiconductor pillar 616 and the third cavity 636, and at least part of the blocking layer 620 is located between the second cavity 640 and the third cavity 636.

As shown in FIG. 10C, in some examples, each semiconductor pillar 616 extends along a Z direction that is perpendicular to a plane formed by the X direction and the Y direction, the third cavity 636 has two opposite surfaces along the Z direction, and the surface of the third cavity 636 away from the second cavity 640 has a convex shape towards a direction away from the second cavity 640.

Here, each gate line group 648 comprises two gate lines 646 extending along the Y direction.

Here, the gate structure 632 comprises a gate dielectric layer 642 covering the sidewall of the semiconductor pillar 616 and a gate layer 644 covering the gate dielectric layer 642.

Here, the semiconductor pillar 616 comprises, along the Z direction, a source 650, a drain 652 and a channel region 654 between the source 650 and the drain 652. The semiconductor device 600 comprises a bit line 656 connected with the plurality of drains 652 arranged along the X direction, and a memory capacitor connected with the source 650.

Examples of the present disclosure provide a semiconductor device and a manufacturing method thereof. The semiconductor device comprises: a plurality of semiconductor pillars arranged along a first direction and a second direction, wherein the first direction intersects the second direction; a plurality of gate lines spaced apart along the first direction, wherein each of the plurality of gate lines extends along the second direction and is connected with the plurality of semiconductor pillars arranged along the second direction; a first cavity located between two adjacent ones of the plurality of gate lines along the first direction and extending along the second direction; a plurality of bit lines spaced apart along the second direction, wherein each of the plurality of bit lines extends along the first direction and is connected with the plurality of semiconductor pillars arranged along the first direction; and a second cavity located between two adjacent ones of the plurality of bit lines along the second direction and extending along the first direction, wherein the second cavity and the first cavity are connected. In the examples of the present disclosure, the first cavity between two adjacent ones of the gate lines and the second cavity between two adjacent ones of the bit lines are connected, which is beneficial to reduce the capacitive coupling effect between the adjacent gate lines and between the adjacent bit lines, so as to improve the performance of the semiconductor device.

In view of this, examples of the present disclosure provide a semiconductor device and a manufacturing method thereof.

In order to achieve the above purpose, the technical solution of the present disclosure is as follows:

In a first aspect, examples of the present disclosure provide a semiconductor device which comprises a plurality of semiconductor pillars arranged along a first direction and a second direction, wherein the first direction intersects the second direction; a plurality of gate lines spaced apart along the first direction, wherein each of the plurality of gate lines extends along the second direction and is connected with the plurality of semiconductor pillars arranged along the second direction; a first cavity located between two adjacent ones of the plurality of gate lines along the first direction and extending along the second direction; a plurality of bit lines spaced apart along the second direction, wherein each of the plurality of bit lines extends along the first direction and is connected with the plurality of semiconductor pillars arranged along the first direction; and a second cavity located between two adjacent ones of the plurality of bit lines along the second direction and extending along the first direction, wherein the second cavity and the first cavity are connected.

In some examples, the plurality of gate lines comprise a plurality of gate line groups spaced apart along the first direction, and each of the plurality of gate line groups comprises two gate lines spaced apart along the first direction, and is located between two adjacent ones of the plurality of semiconductor pillars along the first direction. The first cavity is located between the two gate lines in the same gate line group.

In some examples, the semiconductor device further comprises a third cavity located between two adjacent ones of the plurality of gate line groups along the first direction and extending along the second direction, wherein the third cavity is located between two adjacent ones of the plurality of semiconductor pillars along the first direction, and the first cavity, the second cavity and the third cavity are connected.

In some examples, each of the semiconductor pillars extends along a third direction that is perpendicular to a plane formed by the first direction and the second direction, the third cavity has two opposite surfaces along the third direction, and a surface of the third cavity away from the second cavity is a flat surface.

In some examples, the semiconductor device further comprises a third cavity located between two adjacent ones of the plurality of gate line groups along the first direction and extending along the second direction, wherein the third cavity is located between two adjacent ones of the plurality of semiconductor pillars along the first direction, and the second cavity and the third cavity are not connected; and a blocking layer at least covering part of the third cavity, wherein at least part of the blocking layer is located between the semiconductor pillar and the third cavity, and at least part of the blocking layer is located between the second cavity and the third cavity.

In some examples, each of the semiconductor pillars extends along a third direction that is perpendicular to a plane formed by the first direction and the second direction, the third cavity has two opposite surfaces along the third direction, and a surface of the third cavity away from the second cavity has a convex shape towards a direction away from the second cavity.

In some examples, each of the semiconductor pillars comprises, along the third direction, a source, a drain and a channel region between the source and the drain. The semiconductor device further comprises a gate structure located on at least a sidewall of the semiconductor pillar, wherein the gate structures of the plurality of semiconductor pillars arranged along the second direction are connected to form the gate line.

In some examples, the bit line is connected with a plurality of the drains or the sources arranged along the first direction, and the semiconductor device further comprises a memory capacitor connected with the source or the drain.

In a second aspect, examples of the present disclosure provide a manufacturing method of a semiconductor device, which comprises: providing a semiconductor structure comprising a semiconductor layer as well as a plurality of first trenches extending along a first direction and a plurality of second trenches extending along a second direction in the semiconductor layer, wherein the first trenches are filled with a first sacrificial layer, and the first direction intersects the second direction; forming an initial gate structure and a second sacrificial layer filling the second trench in the second trench; removing part of the semiconductor layer to expose the first sacrificial layer; etching the first sacrificial layer to form a plurality of third trenches extending along the first direction and arranged along the second direction; removing part of the initial gate structure and the second sacrificial layer in the second trench through the third trench to divide one initial gate structure into two gate structures and to form a first cavity; and forming a first covering layer sealing the third trench to form a second cavity in the third trench, wherein the first cavity and the second cavity are connected.

In some examples, the forming the initial gate structure and the second sacrificial layer filling the second trench in the second trench comprises: forming a first dielectric layer covering a sidewall and bottom of the second trench; forming the initial gate structure covering the sidewall and the bottom of the second trench; filling a sacrificial material in the second trench to form the second sacrificial layer; back-etching part of the initial gate structure and the second sacrificial layer, wherein surfaces of the initial gate structure and the second sacrificial layer are lower than a surface of the semiconductor layer; and filling a dielectric material in the second trench.

In some examples, the semiconductor structure further comprises a plurality of fourth trenches extending along the second direction, and the second trenches and the fourth trenches are arranged alternately along the first direction, wherein depths of the first trenches are greater than depths of the fourth trenches.

In some examples, the method further comprises: forming a second dielectric layer covering a sidewall and bottom of the fourth trench; filling a sacrificial material in the fourth trench to form a third sacrificial layer; back-etching part of the third sacrificial layer, wherein a surface of the third sacrificial layer is lower than a surface of the semiconductor layer; and filling a dielectric material in the fourth trench.

In some examples, at the same time as removing part of the initial gate structure and the second sacrificial layer in the second trench through the third trench to divide one initial gate structure into two gate structures and to form the first cavity, the method further comprises: removing the third sacrificial layer in the fourth trench through the third trench to form a third cavity in the fourth trench, wherein the first cavity, the second cavity and the third cavity are connected.

In some examples, the method further comprises: forming a second dielectric layer covering the sidewall and the bottom of the fourth trench; forming a blocking layer covering the sidewall and the bottom of the fourth trench, back-etching part of the blocking layer, wherein a surface of the blocking layer is lower than a surface of the semiconductor layer; and forming a second covering layer sealing the fourth trench to form a third cavity in the fourth trench, wherein the second cavity and the third cavity are not connected.

In a third aspect, examples of the present disclosure provide a semiconductor device comprising a plurality of semiconductor pillars arranged along a first direction and a second direction, wherein the first direction intersects the second direction; a plurality of gate line groups spaced apart along the first direction, wherein each of the plurality of gate line groups comprises two gate lines spaced apart along the first direction, and is located between two adjacent ones of the plurality of semiconductor pillars along the first direction, and each of the gate lines extends along the second direction and is connected with the plurality of semiconductor pillars arranged along the second direction; a third cavity located between two adjacent ones of the plurality of gate line groups along the first direction and extending along the second direction; a plurality of bit lines spaced apart along the second direction, wherein each of the plurality of bit lines extends along the first direction and is connected with the plurality of semiconductor pillars arranged along the first direction; and a second cavity located between two adjacent ones of the plurality of bit lines along the second direction and extending along the first direction.

In some examples, the third cavity is located between two adjacent ones of the plurality of semiconductor pillars along the first direction, and the second cavity and the third cavity are connected.

In some examples, each of the plurality of semiconductor pillars extends along a third direction that is perpendicular to a plane formed by the first direction and the second direction, the third cavity has two opposite surfaces along the third direction, and a surface of the third cavity away from the second cavity is a flat surface.

In some examples, the third cavity is located between two adjacent ones of the plurality of semiconductor pillars along the first direction, and the second cavity and the third cavity are not connected. The semiconductor device further comprises a blocking layer at least covering part of the third cavity, wherein at least part of the blocking layer is located between the semiconductor pillar and the third cavity, and at least part of the blocking layer is located between the second cavity and the third cavity.

In some examples, each of the plurality of semiconductor pillars extends along a third direction that is perpendicular to a plane formed by the first direction and the second direction, the third cavity has two opposite surfaces along the third direction, and a surface of the third cavity away from the second cavity has a convex shape towards a direction away from the second cavity.

In some examples, each of the semiconductor pillars comprises, along the third direction, a source, a drain and a channel region between the source and the drain. The semiconductor device further comprises a gate structure located on at least a sidewall of the semiconductor pillar, wherein the gate structures of the plurality of semiconductor pillars arranged along the second direction are connected to form the gate line.

In some examples, the bit line is connected with a plurality of the drains or the sources arranged along the first direction, and the semiconductor device further comprises a memory capacitor connected with the source or the drain.

Examples of the present disclosure provide a semiconductor device and a manufacturing method thereof. In the examples of the present disclosure, the first cavity between two adjacent ones of the gate lines and the second cavity between two adjacent ones of the bit lines are connected, which is beneficial to reduce a capacitive coupling effect between the adjacent gate lines and between the adjacent bit lines, so as to improve the performance of the semiconductor device.

It is to be understood that, references to “one example” or “an example” throughout the specification indicate that particular features, structures, or characteristics related to the example are comprised in at least one example of the present disclosure. Therefore, “in one example” or “in an example” presented throughout this specification does not necessarily refer to the same example. Furthermore, these particular features, structures, or characteristics may be incorporated in one or more examples in any suitable manner. It is to be understood that, in various examples of the present disclosure, sequence numbers of the above processes do not indicate a sequence of execution, and the sequence of execution of various processes shall be determined by functionalities and intrinsic logics thereof, and shall constitute no limitation on the implementation of examples of the present disclosure. The above sequence numbers of the examples of the present disclosure are only for description, and do not represent advantages and disadvantages of the examples.

The above descriptions are merely some implementations of the present disclosure, and are not intended to limit the protection scope of the present disclosure. Any equivalent structure transformation made by using the contents of the specification and the drawings of the present disclosure under the inventive concept of the present disclosure, or direct/indirect application to other related technical fields are encompassed within the protection scope of the present disclosure.

What is claimed is:

1. A semiconductor device, comprising:
a plurality of semiconductor pillars arranged along a first direction and a second direction, wherein the first direction intersects the second direction;
a plurality of gate lines spaced apart along the first direction, wherein each of the plurality of gate lines extends along the second direction and is connected with the plurality of semiconductor pillars arranged along the second direction;
a first cavity located between two adjacent ones of the plurality of gate lines along the first direction and extending along the second direction;
a plurality of bit lines spaced apart along the second direction, wherein each of the plurality of bit lines extends along the first direction and is connected with the plurality of semiconductor pillars arranged along the first direction; and
a second cavity located between two adjacent ones of the plurality of bit lines along the second direction and extending along the first direction, wherein the second cavity and the first cavity are connected.

2. The semiconductor device of claim 1, wherein the plurality of gate lines include a plurality of gate line groups spaced apart along the first direction, and each of the plurality of gate line groups includes two gate lines spaced apart along the first direction, and is located between two adjacent ones of the plurality of semiconductor pillars along the first direction, and the first cavity is located between the two gate lines in a same gate line group.

3. The semiconductor device of claim 2, further including a third cavity located between two adjacent ones of the plurality of gate line groups along the first direction and extending along the second direction, wherein the third cavity is located between two adjacent ones of the plurality of semiconductor pillars along the first direction, and the first cavity, the second cavity and the third cavity are connected.

4. The semiconductor device of claim 3, wherein each of the semiconductor pillars extends along a third direction that is perpendicular to a plane formed by the first direction and the second direction, and the third cavity has two opposite surfaces along the third direction, and a surface of the third cavity away from the second cavity is a flat surface.

5. The semiconductor device of claim 2, further including:
a third cavity located between two adjacent ones of the plurality of gate line groups along the first direction and extending along the second direction, wherein the third cavity is located between two adjacent ones of the plurality of semiconductor pillars along the first direction, and the second cavity and the third cavity are not connected; and
a blocking layer at least covering part of the third cavity, wherein at least part of the blocking layer is located between a semiconductor pillar and the third cavity, and at least part of the blocking layer is located between the second cavity and the third cavity.

6. The semiconductor device of claim 5, wherein each of the plurality of semiconductor pillars extends along a third direction that is perpendicular to a plane formed by the first direction and the second direction, and the third cavity has two opposite surfaces along the third direction, and a surface of the third cavity away from the second cavity has a convex shape towards a direction away from the second cavity.

7. The semiconductor device of claim 4, wherein each of the semiconductor pillars includes, along the third direction, a source, a drain and a channel region between the source and the drain, and the semiconductor device further includes a gate structure located on at least a sidewall of a semiconductor pillar, wherein the gate structures of the plurality of semiconductor pillars arranged along the second direction are connected to form a gate line.

8. The semiconductor device of claim 7, wherein a bit line is connected with a plurality of drains or sources arranged along the first direction, and the semiconductor device further includes a memory capacitor connected with the source or the drain.

9. A manufacturing method of a semiconductor device, comprising:
providing a semiconductor structure including a semiconductor layer as well as a plurality of first trenches extending along a first direction and a plurality of second trenches extending along a second direction in the semiconductor layer, wherein the first trenches are filled with a first sacrificial layer, and the first direction intersects the second direction;
forming an initial gate structure and a second sacrificial layer filling the second trench in the second trench;
removing part of the semiconductor layer to expose the first sacrificial layer;
etching the first sacrificial layer to form a plurality of third trenches extending along the first direction and arranged along the second direction;
removing part of the initial gate structure and the second sacrificial layer in the second trench through the third trench to divide one initial gate structure into two gate structures and to form a first cavity; and
forming a first covering layer sealing the third trench to form a second cavity in the third trench, wherein the first cavity and the second cavity are connected.

10. The manufacturing method of claim 9, wherein the forming the initial gate structure and the second sacrificial layer filling the second trenches in the second trenches further includes:
forming a first dielectric layer covering a sidewall and bottom of the second trenches;
forming the initial gate structure covering the sidewall and the bottom of the second trenches;
filling a sacrificial material in the second trenches to form the second sacrificial layer;
back-etching part of the initial gate structure and the second sacrificial layer, wherein surfaces of the initial gate structure and the second sacrificial layer are lower than a surface of the semiconductor layer; and
filling a dielectric material in the second trenches.

11. The manufacturing method of claim 9, wherein the semiconductor structure further includes a plurality of fourth trenches extending along the second direction, and the second trenches and the fourth trenches are arranged alternately along the first direction, wherein depths of the first trenches are greater than depths of the fourth trenches.

12. The manufacturing method of claim 11, further including:
forming a second dielectric layer covering a sidewall and bottom of the fourth trenches;
filling a sacrificial material in the fourth trenches to form a third sacrificial layer;
back-etching part of the third sacrificial layer, wherein a surface of the third sacrificial layer is lower than a surface of the semiconductor layer; and
filling a dielectric material in the fourth trenches.

13. The manufacturing method of claim 12, wherein, at the same time as removing part of the initial gate structure and the second sacrificial layer in the second trench through the third trenches to divide one initial gate structure into two gate structures and to form the first cavity, the method further includes removing the third sacrificial layer in the fourth trench through the third trenches to form a third cavity in the fourth trench, wherein the first cavity, the second cavity and the third cavity are connected.

14. The manufacturing method of claim 11, further including:
forming a second dielectric layer covering a sidewall and bottom of the fourth trenches;
forming a blocking layer covering the sidewall and the bottom of the fourth trenches;
back-etching part of the blocking layer, wherein a surface of the blocking layer is lower than a surface of the semiconductor layer; and
forming a second covering layer sealing the fourth trenches to form a third cavity in the fourth trenches, wherein the second cavity and the third cavity are not connected.

15. A semiconductor device, comprising:
a plurality of semiconductor pillars arranged along a first direction and a second direction, wherein the first direction intersects the second direction;
a plurality of gate line groups spaced apart along the first direction, wherein each of the plurality of gate line groups includes two gate lines spaced apart along the first direction, and is located between two adjacent ones of the plurality of semiconductor pillars along the first direction, and each of the gate lines extends along the second direction and is connected with the plurality of semiconductor pillars arranged along the second direction;
a third cavity located between two adjacent ones of the plurality of gate line groups along the first direction and extending along the second direction;
a plurality of bit lines spaced apart along the second direction, wherein each of the plurality of bit lines extends along the first direction and is connected with the plurality of semiconductor pillars arranged along the first direction; and
a second cavity located between two adjacent ones of the plurality of bit lines along the second direction and extending along the first direction.

16. The semiconductor device of claim 15, wherein the third cavity is located between two adjacent ones of the plurality of semiconductor pillars along the first direction, and the second cavity and the third cavity are connected.

17. The semiconductor device of claim 16, wherein each of the plurality of semiconductor pillars extends along a third direction that is perpendicular to a plane formed by the first direction and the second direction, and the third cavity has two opposite surfaces along the third direction, and a surface of the third cavity away from the second cavity is a flat surface.

18. The semiconductor device of claim 15, wherein the third cavity is located between two adjacent ones of the plurality of semiconductor pillars along the first direction, and the second cavity and the third cavity are not connected, and the semiconductor device further includes a blocking layer at least covering part of the third cavity, wherein at least part of the blocking layer is located between a semiconductor pillar and the third cavity, and at least part of the blocking layer is located between the second cavity and the third cavity.

19. The semiconductor device of claim 18, wherein each of the plurality of semiconductor pillars extends along a third direction that is perpendicular to a plane formed by the first direction and the second direction, and the third cavity has two opposite surfaces along the third direction, and a surface of the third cavity away from the second cavity has a convex shape towards a direction away from the second cavity.

20. The semiconductor device of claim 17, wherein each of the semiconductor pillars includes, along the third direction, a source, a drain and a channel region between the source and the drain, and the semiconductor device further includes a gate structure located on at least a sidewall of a semiconductor pillar, wherein the gate structures of the plurality of semiconductor pillars arranged along the second direction are connected to form a gate line, and wherein a bit line is connected with a plurality of drains or sources arranged along the first direction, and the semiconductor device further includes a memory capacitor connected with the source or the drain.
